(19) United States
(12) Patent Application Publication
(10) Pub. No.: US 2024/0176929 A1
(43) Pub. Date: May 30, 2024

(54) ESTIMATION DEVICE, ESTIMATION METHOD, AND COMPUTER PROGRAM

(71) Applicant: GS Yuasa International Ltd., Kyoto-shi, Kyoto (JP)

(72) Inventors: Yosuke OKABE, Kyoto (JP); Motonobu MURAKAMI, Kyoto (JP); Shota YAMAUCHI, Kyoto (JP); Shigeki YAMATE, Kyoto (JP)

(21) Appl. No.: 18/552,813

(22) PCT Filed: Mar. 25, 2022
(86) PCT No.: PCT/JP2022/014251

§ 371 Date: Sep. 27, 2023

(30) Foreign Application Priority Data
Mar. 31, 2021 (JP) JP2021-061200
Mar. 31, 2021 (JP) JP2021-061201
Mar. 31, 2021 (JP) JP2021-061202

(51) Int. Cl. G06F 30/20

(52) U.S. Cl. CPC G06F 30/20

(57) ABSTRACT

Provided are an estimation device, an estimation method, and a computer program.

An estimation device includes: an acquisition unit configured to acquire data relating to a strain generated in an energy storage device; and an estimation unit configured to estimate an internal stress in the energy storage device based on the data acquired by the acquisition unit using a simulation model that expresses a dynamic state inside the energy storage device.

### CROSS REFERENCE TO RELATED APPLICATIONS

This application is a National Stage Application, filed under 35 U.S.C. § 371, of International Application No. PCT/JP2022/014251, filed Mar. 25, 2022, which international application claims priority to and the benefit of Japanese Application No. 2021-061202, filed Mar. 31, 2021, Japanese Application No. 2021-061201, filed March 31, 2021, and Japanese Application No. 2021-061200, filed Mar. 31, 2021; the contents of all of which are hereby incorporated by reference in their entirety.

### BACKGROUND

### Technical Field

The present invention relates to an estimation device, an estimation method, and a computer program.

### Description of Related Art

In recent years, energy storage devices such as lithium ion batteries have been used in a wide range of fields such as power supplies for portable terminals such as notebook personal computers and smartphones, renewable energy storage systems, and power supplies for IoT devices.

The development of lithium ion batteries has been in progress with the aim of achieving a high capacity and a high energy density, and the search for novel electrode materials has been in progress. Pertinent prior art documents include Patent Document 1: JP-A-2016-207318 and Patent Document 2: JP-A-2019-091615.

### BRIEF SUMMARY

In many cases, it has been known that an electrode material capable of achieving a high capacity and a high energy density expands its volume when a battery is charged or discharged or when the battery is deteriorated (see Patent Document 1 and Patent Document 2, for example). In a usual case, the electrodes are placed in a certain housing and are constrained by a mechanical force. Accordingly, an internal stress is generated in the battery due to an expansion of a volume of the battery.

It has been known that an internal stress in a battery affects characteristics of the battery such as an internal resistance of the battery or the precipitation of a reaction product. However, no proposal has been made with respect to a method of carrying out the performance evaluation of a battery or the monitoring of a state of the battery by making an internal stress in the battery and the characteristics of the battery associated with each other.

The present invention has been made in view of such circumstances, and it is an object of the present invention to provide an estimation device, an estimation method, and a computer program for estimating an internal stress generated in a battery as one of behaviors in the battery.

An estimation device includes: an acquisition unit configured to acquire data relating to a strain generated in an energy storage device; and an estimation unit configured to estimate an internal stress in the energy storage device based on the data acquired by the acquisition unit using a simulation model representing a dynamic state in the energy storage device.

An estimation method causes a computer to perform processing to acquire data relating to a strain generated in an energy storage device, and to estimate an internal stress of the energy storage device based on data that the acquisition unit acquires using a simulation model that expresses a dynamic state inside the energy storage device.

According to the above-mentioned configuration, it is possible to estimate an internal stress generated inside the battery as one of behaviors inside the battery.

### BRIEF DESCRIPTION OF THE FIGURES

FIG. 1 is a schematic block diagram illustrating the entire configuration of an estimation system according to an embodiment 1.

FIG. 2 is an explanatory view for explaining the configuration of an energy storage device.

FIG. 3 is an explanatory view for explaining the internal configuration of a solid electrolyte layer.

FIG. 4 is a block diagram illustrating the internal configuration of an estimation device.

FIG. 5 is a flowchart for explaining steps of estimating an internal stress in the embodiment 1.

FIG. 6 is a graph illustrating a relationship between an internal stress and an ohmic resistance of the energy storage device.

FIG. 7 is a circuit diagram illustrating an example of an equivalent circuit model.

FIG. 8 is a block diagram illustrating the internal configuration of the estimation device according to an embodiment 5.

FIG. 9 is an explanatory view illustrating a method of calculating an effective diffusion coefficient.

FIG. 10 is an explanatory view illustrating a method of calculating an effective diffusion coefficient in an all-solid-state battery.

FIG. 11A is a view illustrating a result of calculation of an effective diffusion coefficient in the all-solid-state battery.

FIG. 11B is a view illustrating a result of calculation of an effective diffusion coefficient in the all-solid-state battery.

FIG. 11C is a view illustrating a result of calculation of an effective diffusion coefficient in the all-solid-state battery.

FIG. 12 is a graph illustrating a relationship between a contact area ratio and an effective diffusion coefficient.

FIG. 13 is a flowchart illustrating steps of performing arithmetic processing that the estimation device according to the embodiment 5 performs.

FIG. 14 is a flowchart illustrating steps of performing arithmetic processing that an estimation device according to an embodiment 6 performs.

FIG. 15 is an explanatory view for describing the configuration of an energy storage device.

FIG. 16 is a graph illustrating an example of a relationship between a generation amount of precipitates and an inherent strain.

FIG. 17 is a graph illustrating another example of a relationship between a generation amount of precipitates and an inherent strain.

FIG. 18 is a flowchart illustrating steps of calculating the stress/strain distribution.

FIG. 19 is a circuit diagram illustrating an example of an equivalent circuit model.

### DETAILED DESCRIPTION OF VARIOUS EMBODIMENTS

An estimation device includes: an acquisition unit configured to acquire data relating to a strain generated in an energy storage device; and an estimation unit configured to estimate an internal stress in the energy storage device based on the data acquired by the acquisition unit using a simulation model representing a dynamic state in the energy storage device.

The data relating to a strain may be measurement data acquired by a strain sensor.

According to such a configuration, based on data of a strain generated in the energy storage device, it is possible to directly estimate an internal stress of the energy storage device that cannot be directly observed by simulation.

The estimation device may be configured such that the simulation model includes, as parameters, an inherent strain in the energy storage device and a binding force applied to the energy storage device, and the estimation device may output data relating to the internal stress in the energy storage device in response to inputting of data on the strain. With such a configuration, for example, an internal stress of the energy storage device can be estimated by taking into account a balance of a force based on a binding force applied to the energy storage device, an inherent strain of the energy storage device, and an internal stress of the energy storage device.

In the estimation device, the inherent strain may be a strain of the energy storage device generated attributed to at least one of isolation of active material particles, the growth of precipitates and thermal expansion of the energy storage device. With such a configuration, it is possible to estimate an internal stress of the energy storage device by taking into account an inherent strain attributed to at least one of the isolation of active material particles, the growth of precipitates and the thermal expansion of the energy storage device.

In the estimation device, the estimation unit may include a state estimator that uses a nonlinear filter. With such a configuration, a nonlinear filter such as an ensemble Kalman filter, a particle filter, an extended Kalman filter, or an unscented Kalman filter or the like is used. Accordingly, even in a case where linearity is not assumed between an inherent strain and an internal stress, it is possible to favorably estimate an internal stress of the energy storage device.

In the estimation device, the estimation unit may estimate an internal resistance of the energy storage device as a function of the internal stress. With such a configuration, an internal resistance of the energy storage device can be estimated based on a value of the internal stress and hence, it is possible to estimate an electrochemical phenomenon of the energy storage device that reflects the internal stress.

In the estimation device, the energy storage device may be an all-solid-state battery in which an electrolyte is a solid body. With such a configuration, it is possible to estimate a value of an internal stress that decisively affects the performance of an all-solid-state battery.

In the estimation device, the energy storage device may be a battery that includes a negative electrode made of metal lithium. With such a configuration, with respect to the battery where precipitates are liable to be generated, it is possible to estimate an internal stress attributed to the growth of the precipitates.

In the energy storage device described above, a type of a positive electrode material and a type of electrolyte are not limited. The energy storage device may be an all-solid-state battery that uses a negative electrode made of metal lithium. Alternatively, the energy storage device may be a lithium sulfur battery (LiS battery) that includes a positive electrode made of sulfur. Even when a battery is neither an all-solid-state battery nor a battery that uses a negative electrode made of metal lithium, substantially the same logic is established with respect to an energy storage device where a volume of the electrode is expanded along with charging and discharging or deterioration of the battery.

An estimation device includes an arithmetic operation unit that simulates an electrochemical phenomenon of an all-solid-state battery including the solid electrolyte using a simulation model that includes a contact area between active material particles and the solid electrolyte as a parameter.

With such a configuration, an electrochemical phenomenon of the all-solid-state battery can be simulated based on the contact area that is one of characteristic parameters of the all-solid-state battery.

An estimation device includes an arithmetic operation unit that, with respect to an energy storage device in which precipitates are generated corresponding to charging and discharging, calculates an inherent strain of the energy storage device based on a generation amount and a precipitation mode of the precipitates, and calculates the distribution of a stress or a strain generated in the energy storage device based on the calculated inherent strain. With such a configuration, the inherent strain of the energy storage device can be calculated, and the distribution of the stress or the strain can be calculated based on the calculated inherent strain.

An estimation method causes a computer to perform processing to acquire data relating to a strain generated in an energy storage device, and to estimate an internal stress of the energy storage device based on data that the acquisition unit acquires using a simulation model that expresses a dynamic state inside the energy storage device.

With such a configuration, it is possible to estimate an internal stress of the energy storage device that cannot be directly observed based on data on a strain that is generated in the energy storage device.

The estimation method, using a simulation model that includes a contact area between active material particles and a solid electrolyte as a parameter, performs processing to simulate an electrochemical phenomenon of an all-solid-state battery that includes the solid electrolyte using a computer.

With such a configuration, an electrochemical phenomenon of the all-solid-state battery can be simulated based on the contact area that is one of characteristic parameters of the all-solid-state battery.

The estimation method, with respect to an energy storage device where precipitates are generated corresponding to charging and discharging, calculates an inherent strain of the energy storage device based on a generation amount and a precipitation mode of the precipitates, and performs processing of calculating the distribution of a stress or a strain generated in the energy storage device based on the calculated inherent strain using a computer. With such a configuration, the inherent strain of the energy storage device can be calculated, and the distribution of the stress or the strain can be calculated based on the calculated inherent strain.

A computer program causes a computer to perform processing to simulate an electrochemical phenomenon of an all-solid-state battery including the solid electrolyte using a simulation model that includes a contact area between an active material particle and a solid electrolyte as a parameter.

Unlike an electrolyte solution based lithium ion battery, an all-solid-state battery has a large contact resistance unless a contact area between active material particles and a solid electrolyte is positively increased. That is, the all-solid-state battery has a characteristic that the flow of electricity is increased by applying a pressure to the all-solid-state battery from the outside thus increasing a contact area between active material particles and a solid electrolyte.

According to the above-mentioned configuration, an electrochemical reaction of an all-solid-state battery can be simulated based on a contact area that is one of characteristic parameters of all-solid-state battery.

In the computer program, the simulation model may define the relationship between the contact area and an effective diffusion coefficient of the active material particles. The computer program may cause the computer to perform processing to estimate the effective diffusion coefficient of the active material particles based on a value of the contact area. With such a configuration, by associating the value of the contact area with the effective diffusion coefficient of active material particles, it is possible to simulate an electrochemical phenomenon of an all-solid-state battery based on the value of the contact area.

In the computer program, the simulation model may define the relationship between the contact area and an effective ionic conductivity of the active material particles. The computer program may cause the computer to perform processing to estimate the effective ionic conductivity of the active material particles based on a value of the contact area. With such a configuration, by associating the value of the contact area with the effective ionic conductivity of active material particles, it is possible to simulate an electrochemical phenomenon of an all-solid-state battery based on the value of the contact area.

In the computer program, the contact area may be a function of an internal stress of an all-solid-state battery, and the computer program may cause the computer to perform processing to simulate an electrochemical phenomenon of the all-solid-state battery based on a value of the internal stress. With such a configuration, by associating the value of the contact area with a value of an internal stress, it is possible to simulate an electrochemical phenomenon of an all-solid-state battery based on the value of the internal stress.

In the computer program, using a strain sensor that measures a strain generated in the all-solid-state battery, measured data relating to the strain may be acquired, and the computer program may cause the computer to perform processing to estimate an internal stress of the all-solid-state battery based on the acquired measured data using a model expressing a dynamic state inside all-solid-state battery. With such a configuration, the internal stress can be estimated based on the data relating to the strain measured by the sensor, and an electrochemical phenomenon of the all-solid-state battery can be simulated based on a value of the estimated internal stress.

In the computer program, an internal resistance of the all-solid-state battery may be a function of the internal stress, and the computer program may cause the computer to perform processing to estimate a value of the internal resistance based on the value of the internal stress. With such a configuration, by associating the value of the internal stress with the value of the internal resistance, the internal resistance of the all-solid-state battery can be estimated.

A computer program, with respect to the energy storage device that generates precipitates corresponding to charging or discharging, causes the computer to calculate an inherent strain of the energy storage device based on a generation amount and a precipitation mode of the precipitates, and to perform the processing of calculating the distribution of a stress or a strain generated in the energy storage device based on the calculated inherent strain.

In a case where charging and discharging of the energy storage device is repeated, precipitates are precipitated inside the energy storage device. For example, in a lithium metal battery where the increase of energy density is expected, the lithium metal battery is a battery that uses lithium metal performing a negative electrode and hence, due to the repetition of charging and discharging, precipitates (dendrite or the like) precipitates in a sparse manner on a surface of the negative electrode. It is known that besides a lithium metal battery, precipitates such as metal are precipitated in various modes with respect to various batteries such as a lithium ion battery, an all-solid-state battery and the like. Particularly, in a case where irregularities exist in an internal stress or a strain with respect to batteries, the growth of precipitates is liable to be accelerated locally. The growth of the precipitates can become a factor that causes a change in battery characteristics, the expansion of the battery and the like.

To suppress the growth of the precipitates, it is effective to apply binding force from the outside of a battery so as to enable the generation of a uniform stress inside the battery. However, a method of estimating the distribution of a stress or a strain inside the battery has not been proposed up to now.

According to the above-mentioned configuration, an inherent strain of the energy storage device is calculated, and the distribution of the stress or the strain can be calculated based on the calculated inherent strain.

In the computer program, a generation rate of the precipitates may be described as a function of a stress generated in a field of a generation reaction. The computer program may cause the computer to perform the processing of calculating the generation amount based on the generation rate of the precipitates calculated by the function. With such a configuration, the generation amount can be calculated based on the generation rate of the precipitates, and an inherent strain can be calculated based on the generation amount of the calculated precipitates.

The computer program may cause the computer to perform processing to simulate an electrochemical phenomenon of the energy storage device based on the generation amount and a stress field. With such a configuration, an electrochemical phenomenon that includes a change in an internal resistance of the energy storage device and the like can be simulated based on a generation amount of the precipitates and a stress field of the energy storage device.

The computer program may cause the computer to perform processing to simulate a thermal phenomenon of the energy storage device based on the generation amount and the precipitate mode. With such a configuration, a thermal phenomenon that includes a behavior in temperature of the energy storage device can be simulated based on a generation amount of the precipitates and a precipitation mode.

The computer program may cause the computer to perform processing to calculate a gas generation amount in the energy storage device, and to calculate the distribution of a stress or a strain generated in the energy storage device based on the calculated gas generation amount. With such a configuration, the distribution of a stress or a strain in the energy storage device can be calculated based on an amount of gas generated in the energy storage device.

Hereinafter, the present invention will be specifically described with reference to the drawings illustrating embodiments of the present invention.

(Embodiment 1)

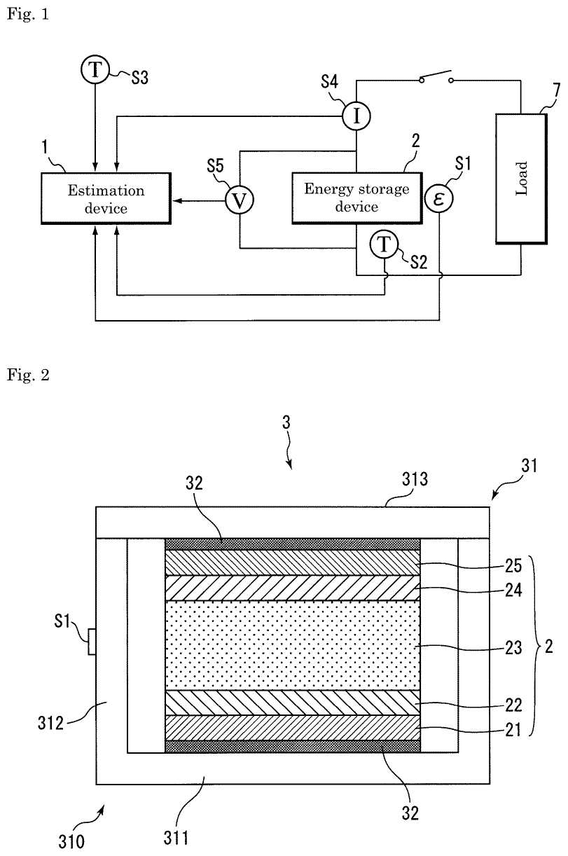

FIG. 1 is a schematic block diagram illustrating the entire configuration of an estimation system according to an embodiment 1. The estimation system according to the embodiment 1 includes an estimation device 1 and an energy storage device 2. The estimation device 1 is, for example, a device such as a battery management unit (BMU) or the like. The estimation device 1 estimates an internal stress in the energy storage device 2 by a method described later, and outputs information relating to the estimated internal stress. In the example of FIG. 1, the estimation device 1 and the energy storage device 2 are described as separate bodies for the sake of convenience. However, the estimation device 1 and the energy storage device 2 may be formed as an integral unit. Further, the estimation device 1 may be an information processing device such as a computer or a server device that is communicably connected to a battery system that includes the energy storage device 2. It is unnecessary that the estimation device 1 is disposed close to the energy storage device 2. The estimation device 1 may be installed in a server room disposed in a different building, or may be installed at a remote place in Japan or outside Japan. Furthermore, the energy storage device 2 may exist in the atmosphere or in the space. Alternately, both the estimation device 1 may be on the earth, or both the energy storage device 2 and the estimation device 1 may be in the atmosphere or in the space.

The energy storage device 2 according to the embodiment 1 is, for example, an all-solid-state battery. During discharging, the energy storage device 2 is connected to a load 7. The energy storage device 2 supplies direct current (DC) electricity to the load 7 that is connected to the energy storage device 2. During charging, the energy storage device 2 is connected to a charging device (not illustrated). The energy storage device 2 stores electricity supplied from the charging device connected to the energy storage device. The energy storage device 2 is not limited to an all-solid-state battery, and may be any battery provided that the battery is a battery that expands.

The estimation system includes various sensors for measuring a state of the energy storage device 2. An example of the sensor that the estimation system includes is a strain sensor S1. The strain sensor S1 measures a strain generated in the energy storage device 2 in time series, and outputs data indicating a result of measurement to the estimation device 1.

The estimation system may include a temperature sensor S2 that measures a temperature of the energy storage device 2. The temperature sensor S2 measures a temperature of the energy storage device 2 in time series, and outputs data indicating a result of measurement to the estimation device 1. Further, the estimation system may include a temperature sensor S3 that measures an ambient temperature around the energy storage device 2. The temperature sensor S3 measures a temperature of a surrounding environment in which the energy storage device 2 is disposed, and outputs data indicating a result of measurement to the estimation device 1.

The estimation system may include an ammeter S4 that measures a current that flows in the energy storage device 2. The ammeter S4 measures a current that flows in the energy storage device 2 in time series, and outputs data indicating a result of measurement to the estimation device 1. The estimation device system may, further, include a voltmeter S5 that measures a voltage of the energy storage device 2. The voltmeter S5 measures a voltage of the energy storage device 2 in time series, and outputs data indicating a result of measurement to the estimation device 1.

The estimation device 1 acquires measurement data measured by various sensors, and estimates an internal stress in the energy storage device 2 based on the acquired measurement data. Hereinafter, the configuration of the energy storage device 2 is described in detail.

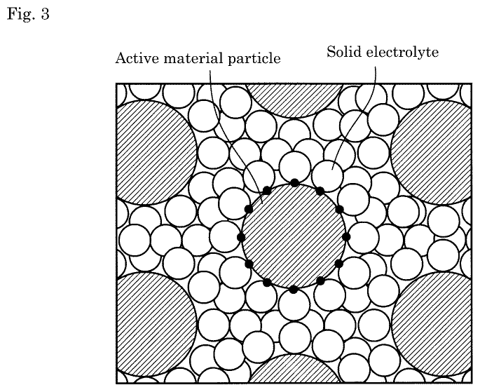

FIG. 2 is an explanatory view for describing the configuration of the energy storage device 2. The energy storage device 2 is, for example, an all-solid-state battery that includes a stacked body formed of a positive electrode current collector layer 21, a positive active material layer 22, a solid electrolyte layer 23, a negative active material layer 24, and a negative electrode current collector layer 25.

The positive electrode current collector layer 21 is formed in the form of a metal foil, a metal mesh or the like. Metal used for forming the positive electrode current collector layer 21 is a metal having good conductivity such as aluminum, nickel, titanium, or stainless steel. A coating layer for adjusting a contact resistance may be formed on a surface of the positive electrode current collector layer 21. An example of the coating layer is a carbon coating. A thickness of the positive electrode current collector layer 21 is not particularly limited, and is, for example, 0.1 μm or more and 1 mm or less.

The positive active material layer 22 is a layer that contains at least a positive active material. The positive active material layer 22 may contain a solid electrolyte, a conductivity aid, a binder, and the like besides the positive active material. The positive active material layer 22 has a thickness of, for example, 0.1 μm or more and 1 mm or less.

As the positive active material, an appropriate positive active material that can be used for an all-solid-state battery is used. For example, various lithium-containing composite oxides such as lithium cobaltate, lithium nickelate, lithium manganate, and a spinel lithium compound are used as the positive active material. The positive active material is, for example, particles having an average particle size (D50) of 0.5 μm or more and 20 μm or less. The particles constituting the positive active material may be primary particles or secondary particles. The positive active material is not limited to particles, and may be formed in a thin film shape. As the solid electrolyte that is contained in the positive active material layer 22, an inorganic solid electrolyte having relatively high ionic conductivity and having excellent heat resistance is used. As such an inorganic solid electrolyte, an oxide solid electrolyte such as lithium lanthanum zirconate or a sulfide solid electrolyte such as Li₂S-P₂S₅ can be used. As the conductivity aid, a carbon material such as acetylene black or Ketjen black, or a metal material such as nickel, aluminum, or stainless steel is used. As the binder, a material such as butadiene rubber (BR), acrylate butadiene rubber (ABR), or polyvinylidene fluoride (PVdF) is used.

The solid electrolyte layer 23 is a layer that contains at least a solid electrolyte. The solid electrolyte layer 23 may contain a binder or the like besides a solid electrolyte. The solid electrolyte layer 23 has a thickness of, for example, 0.1 μm or more and 1 mm or less. As the solid electrolyte contained in the solid electrolyte layer 23, an inorganic solid electrolyte such as the oxide solid electrolyte or the sulfide solid electrolyte described above is used. As the binder, a binder equal to the binder used in forming the positive active material layer 22 is used.

The negative active material layer 24 is a layer that contains at least a negative active material. The negative active material layer 24 may contain a solid electrolyte, a conductivity aid, a binder or the like besides the negative active material. The negative active material layer 24 has a thickness of, for example, 0.1 μm or more and 1 mm or less.

As the negative active material, an appropriate negative active material that can be used for an all-solid-state battery is used. For example, a metal active material and a carbon active material are used as the negative active material. Examples of the metal active material include Li, In, Al, Si, Sn or the like. The metal active material is not limited to a single metal, and may be a metal composite oxide. As the carbon active material, mesocarbon microbeads (MCMB), high orientation property graphite (HOPG), hard carbon, or soft carbon is named. The negative active material is, for example, particles having an average particle size (D50) of 0.5 μm or more and 20 μm or less. The particles constituting the negative active material may be primary particles or secondary particles. The negative active material is not limited to particles, and may be formed in a thin film shape. As the solid electrolyte, the conductivity aid, and the binder used for the negative active material layer 24, corresponding materials substantially equal to the solid electrolyte, the conductivity aid, and the binder used for the positive active material layer 22 are appropriately used.

The negative electrode current collector layer 25 is formed in the form of a metal foil, a metal mesh or the like. Metal used for forming the negative electrode current collector layer 25 is a metal having good conductivity such as copper, nickel, titanium, or stainless steel. A coating layer for adjusting a contact resistance may be formed on a surface of the negative electrode current collector layer 25. An example of the coating layer is a carbon coating. A thickness of the negative electrode current collector layer 25 is not particularly limited, and is, for example, 0.1 μm or more and 1 mm or less.

The energy storage device 2 is bound by a binding member 3. The binding member 3 includes, for example, a case 31 that houses the energy storage device 2 and elastic members 32 that are disposed in the case 31 in a compressed state. The case 31 is, for example, a rectangular parallelepiped container, and includes: a case body 310 that is formed of a bottom surface portion 311 and a side surface portions 312; and a lid body 313 that closes an opening of the case body 310. The case body 310 (the bottom surface portion 311 and the side surface portions 312) and the lid body 313 are made of weldable metal such as stainless steel, aluminum, or an aluminum alloy, for example. Alternatively, the case body 310 (the bottom surface portion 311 and the side surface portion 312) and the lid body 313 may be formed of a resin. The energy storage devices 2 are housed in the case body 310 and, thereafter, the case body 310 is sealed by the lid body 313.

The elastic member 32 is disposed in a compressed state between the lowermost layer (the positive electrode current collector layer 21 in the example illustrated in FIG. 2) and the bottom surface portion 311 of the energy storage device 2 and between the uppermost layer (the negative electrode current collector layer 25 in the example of FIG. 2) and the lid body 313 of the energy storage device 2. The elastic member 32 is, for example, a rubber-like sheet. The elastic members 32 apply a binding force in the stacking direction (from above and below in the vertical direction in the drawing) to the energy storage device 2 by an elastic force that the elastic members 32 possess.

In the example illustrated in FIG. 2, a binding force is applied to the energy storage device 2 by disposing the elastic members 32 inside the case 31. Alternatively, a binding force may be applied to the energy storage device 2 by filling the case 31 with a high pressure fluid. In this case, it is preferable that the fluid be a fluid that does not cause an undesired reaction with the battery material. For example, an inert gas such as nitrogen, dry air, or the like is used as such a fluid. Alternatively, the energy storage devices 2 may be sandwiched by plate members from both sides in the stacking direction, and the plate members may be connected to each other in a state where a binding force is applied to the energy storage devices 2 thus applying the binding force to the energy storage devices 2.

The strain sensor S1 for measuring a strain of the energy storage device 2 is mounted on a place where a strain generated corresponding to an internal stress of the energy storage device 2 can be measured. In the example illustrated in FIG. 2, a strain corresponding to an internal stress of the energy storage device 2 appears on the side surface portion 312 of the case 31. Accordingly, it is preferable that the strain sensor S1 for measuring a strain be mounted on an appropriate portion of the side surface portion 312. Alternatively, the strain sensor SI may be mounted on the bottom surface portion 311 of the case 31 or on the lid body 313. Further, the strain sensor S1 may be mounted on the energy storage device 2.

FIG. 3 is an explanatory view for explaining the internal configuration of the solid electrolyte layer 23. In the example illustrated in FIG. 3, the active material particles are indicated as hatched spheres, and the solid electrolyte is indicated as unhatched spheres. For the sake of simplicity, the conductivity aid and the binder are omitted in FIG. 3. In a conventional electrolyte solution-based lithium ion battery, a surrounding of active material particles is filled with an electrolyte solution, and the active material is in a state where the entire surface of the active material is in contact with the electrolyte solution. On the other hand, in an all-solid-state battery using a solid electrolyte, as indicated by black dots in the drawing, a solid electrolyte and active material particles are brought into contact with each other at minute contact areas (points). The contact area between the solid electrolyte and the active material particles changes depending on a binding force that binds the energy storage device or an internal stress in the energy storage device.

In the all-solid-state battery, a contact area between the solid electrolyte and the active material particles changes corresponding to a binding force or an internal stress, and battery characteristics largely change corresponding to the change in the contact area. In order to accurately estimate the battery characteristics (such as charging and discharging characteristics) of the all-solid-state battery, it is indispensable to estimate an internal stress. In a battery that uses metal lithium for forming the negative electrode, a generation rate of precipitates changes due to an internal stress. Accordingly, the estimation of the internal stress is indispensable.

Next, the configuration of the estimation device 1 will be described.

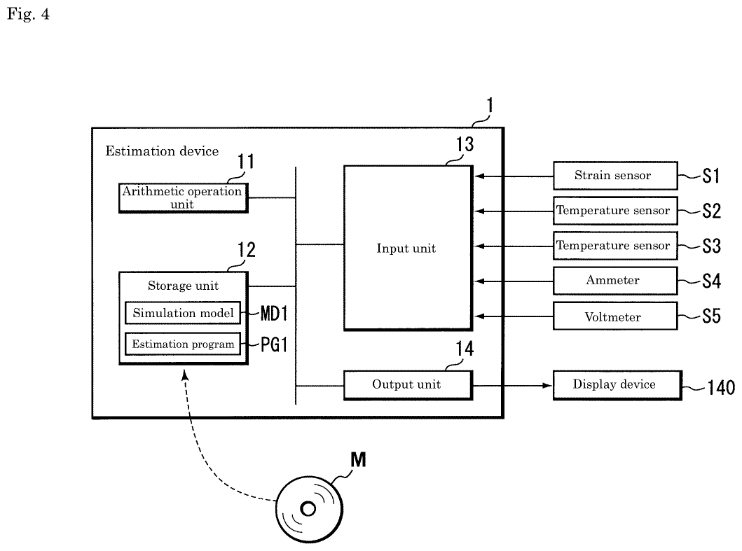

FIG. 4 is a block diagram illustrating the internal configuration of the estimation device 1. The estimation device 1 includes, for example, an arithmetic operation unit (estimation unit) 11, a storage unit 12, an input unit 13, and an output unit 14.

The arithmetic operation unit 11 is an arithmetic operation circuit that includes a central processing unit (CPU), a read only memory (ROM), a random access memory (RAM), and the like. The CPU that the arithmetic operation unit 11 includes executes various computer programs stored in the ROM or the storage unit 12, and controls the operations of the respective hardware unit described above. Accordingly, the arithmetic operation unit 11 makes the entire apparatus function as a state estimator (also referred to as an observer) for estimating an internal stress in the energy storage device 2. Specifically, the arithmetic operation unit 11 executes an arithmetic operation for estimating an internal stress in the energy storage device 2 based on the measurement data of a strain inputted through the input unit 13 using a simulation model MD1 that simulates a dynamic state inside the energy storage device 2. Alternatively, the arithmetic operation unit 11 may execute an arithmetic operation for estimating an internal stress in the energy storage device 2 using virtual data of a strain prepared by a user manually. Alternatively, the arithmetic operation unit 11 may execute an arithmetic operation for estimating an internal stress in the energy storage device 2 using virtual data on a strain generated by the estimation device 1 or an external computer.

Alternatively, the arithmetic operation unit 11 may be a desired processing circuit or a desired arithmetic operation circuit that includes a plurality of CPUs, a multi-core CPU, a graphics processing unit (GPU), a microcomputer, a volatile or nonvolatile memory, and the like. The arithmetic operation unit 11 may have functions such as a timer that measures an elapsed time from a point of time that a measurement start instruction is issued to a point of time that a measurement finish instruction is issued, a counter that counts the number, and a clock that outputs information on date and time.

The storage unit 12 includes a storage device such as a flash memory or a hard disk. The storage unit 12 stores various computer programs and data. The computer program stored in the storage unit 12 includes an estimation program PGI for making a computer execute processing to estimate an internal stress in the energy storage device 2 using the simulation model MD1. It is sufficient that the simulation model MDI be described in the estimation program PG1. The data stored in the storage unit 12 includes: parameters used in the simulation model MD1; parameters used in the estimation program PG1; data generated by the arithmetic operation unit 11, and the like.

The estimation program PGI may be described by a commercially available numerical analysis software or a commercially available programming language such as MATLAB (registered trademark), Amesim (registered trademark), Twin Builder (registered trademark), MATLAB & Simulink (registered trademark), Simplorer (registered trademark), ANSYS (registered trademark), Abaqus (registered trademark), Modelica (registered trademark), VHDL-AMS (registered trademark), C language, C++, or Java (registered trademark). The numerical analysis software may be a circuit simulator referred to 1D-CAE, or may be a simulator such as a finite element method or a finite volume method performed in a 3D shape. Alternatively, a reduced-order model (ROM) based on these may be also used.

The computer program including the estimation program PGI is provided by a non-transitory recording medium M in which the computer program is recorded in a readable manner. The recording medium M is a portable memory such as a CD-ROM, a USB memory, or a secure digital (SD) card. The arithmetic operation unit 11 reads a desired computer program from the recording medium M using a reading device (not illustrated), and stores the read computer program in the storage unit 12. Alternatively, the computer program may be provided via communication.

The input unit 13 includes an interface for connecting the estimation device 1 with various sensors. A strain sensor S1 for measuring a strain generated in the energy storage device 2 is connected to the input unit 13. The arithmetic operation unit 11 acquires measurement data on the strain measured by the strain sensor S1 through the input unit 13.

A temperature sensor S2 that measures a temperature of the energy storage device 2, a temperature sensor S3 that measures an environmental temperature of the energy storage device 2, and the like may be connected to the input unit 13. The temperature sensor S2 is mounted on an appropriate portion of the energy storage device 2 or the case 31 that accommodates the energy storage device 2, and measures a temperature of the energy storage device 2. The temperature sensor S3 is provided around the energy storage device 2 and measures a temperature (environmental temperature) around the energy storage device 2. As the temperature sensors S2 and S3, existing sensors such as a thermocouple and a thermistor are used. The arithmetic operation unit 11 may acquire data on environmental temperature from an external server such as a weather server.

An ammeter S4 for measuring a current flowing through the energy storage device 2 and a voltmeter S5 for measuring a voltage of the energy storage device 2 may be connected to the input unit 13.

The output unit 14 includes a connection interface for connecting the estimation device 1 with an external device. The external device connected to the output unit 14 is a display device 140 that includes a liquid crystal display or the like. In this case, the arithmetic operation unit 11 outputs information relating to an estimated internal stress in the energy storage device 2 from the output unit 14, and makes the output unit 14 display the information on a display device 140. Alternatively, the estimation device 1 may include the display device 140.

Further, the output unit 14 may include a communication interface for communicating with an external device. The external device that is communicably connected to the output unit 14 is a monitoring server that monitors a state of the energy storage device 2. Alternatively, the external device that is communicably connected to the output unit 14 may be a mobile terminal or a control device of an electric vehicle that is operated by electricity supplied from the energy storage device 2.

Hereinafter, the contents of the arithmetic operation processing performed by the estimation device 1 will be described.

The estimation device 1 estimates an internal stress in the energy storage device 2 based on the measurement data of the strain sensor S1 inputted through the input unit 13 using a simulation model that expresses a dynamic state inside the energy storage device 2.

The simulation model that expresses a dynamic state of the inside of the energy storage device 2 is expressed by a force balance equation. For example, the following Formula 1 is used as the force balance equation.

Fₑₓₜ=SE{ϵ−(ϵ_{iso,e}+ϵ_{pre,e})} (1)

In Formula 1, Fₑₓₜ is a binding force that is applied to the energy storage device 2 by the binding member 3. S is a cross-sectional area perpendicular to the binding force that is applied to the energy storage device 2. E is an elastic modulus of the energy storage device 2. ϵ is an elastic strain of the energy storage device 2. ϵ_{iso, e} is an inherent strain of the energy storage device 2 due to the isolation of active material particles, and ϵ_{pre, e} is an inherent strain of the energy storage device 2 due to the growth of precipitates.

In the embodiment 1, as factors that cause a strain in the energy storage device 2, (1) isolation of active material particles and (2) the growth of precipitates are considered.

### (1) Inherent Strain Due to Isolation

The isolation expresses a phenomenon where charge carriers (for example, lithium atoms) are inserted into or are released from the active material particles during charging or discharging so that the expansion and the shrinkage of the active material particles are repeated, whereby the active material particles are broken by a stress. Isolation is also referred to as pulverization or a crack growth. When the active material particle is broken, a gap is generated in the active material particle. As a result, an apparent volume of the active material particle is increased and hence, an inherent strain is generated inside the energy storage device 2.

A progress speed of the inherent strain due to the isolation is expressed by the following Formula 2, for example.

ϵ_{iso,e}^{k+1}=ϵ_{iso,e}^{k}+k_{iso,0}+k_{iso,1}|I|^{α}^{_{iso,1}}+v_{iso,e} (2)

In Formula 2, ϵ_{iso, e} indicates an inherent strain due to isolation. The subscript “iso” indicates isolation, and the subscript “e” indicates an inherent strain. The superscripts “k” and “k+1” indicate time steps. k_{iso, 0}, and k_{iso, 1} are rate coefficients, and respectively indicate a degree of increase in an inherent strain due to isolation with a lapse of time, and a degree of increase in an inherent strain due to the progress of isolation by the supply of electricity. Isolation hardly progresses only by a change with a lapse of time and hence, in many cases, even when k_{iso, 0} is set as k_{iso, 0}=0.0, there arises no problem. I indicates a current flowing through the energy storage device 2. α_{iso, 1} indicates a proportional power constant of a current. v_{iso, e} indicates a disturbance term of the isolation progress.

### (2) Inherent Strain Due to Growth of Precipitates

For example, when lithium metal is used as a material for forming the negative electrode of the energy storage device 2, precipitates may be precipitated on a surface of the negative electrode by repeated charging and discharging over a long period of time. Due to the growth of the precipitates, an inherent strain is generated inside the energy storage device 2.

A progress speed of the inherent strain due to the growth of the precipitates is expressed by the following Formula 3, for example.

ϵ_{pre,c}^{k}+k_{pre,0}(σᵢₙ^{k})+k_{pre,1}(σᵢₙ^{k})|I|^{α}^{_{pre,1}}+v_{pre,e} (3)

In Formula 3, ϵ_{pre, e} indicates an inherent strain due to the growth of precipitates. The subscript “pre” indicates precipitates, and the subscript “e” indicates an inherent strain. The superscripts “k” and “k+1” indicate time steps. k_{pre, 0}, and k_{pre, 1} are rate coefficients. k_{pre, 0} indicates a degree of increase in an inherent strain due to isolation with a lapse of time, and k_{pre, 1} indicates degree of increase in an inherent strain due to the growth of the precipitates by the supply of electricity. σᵢₙ indicates an internal stress of the energy storage device 2. The rate coefficients k_{pre, 0} and k_{pre, 1} both indicate a function of the internal stress σᵢₙ. σᵢₙ may be a function of a location inside the energy storage device. I indicates a current flowing through the energy storage device 2. α_{pre, 1} indicates a proportional power constant of a current. v_{pre, e} indicates a disturbance term of an inherent strain due to the growth of precipitates.

The precipitates may be a sparse lithium metal, a passive film (SEI film), or the like. Even when any precipitates are precipitated inside the energy storage device 2, the progress speed of the inherent strain associated with the growth of the precipitates is expressed by the same formula as Formula 3.

A binding force Fₑₓₜ that is applied to the energy storage device 2 agrees with a tensile force generated in the side surface portion 312 that forms the binding member 3. Accordingly, the binding force Fₑₓₜ is expressed by the following Formula 4.

Fₑₓₜ=S_{ref}E_{ref}ϵref (4)

In Formula 4, E_{ref} is the Young's modulus of the side surface portion 312, ϵ_{ref} is a strain generated in the side surface portion 312 that is measured by the strain sensor S1, and S_{ref} is a cross-sectional area of the side surface portion 312.

A relationship of σᵢₙ=ϵE is established between an internal stress Gin and an elastic strain ϵ of the energy storage device 2. Accordingly, the internal stress σᵢₙ is expressed as follows using a relationship formula formed by combining Formula 1 and Formula 4.

$$\\ \begin{matrix}{σ}_{in}^{{}_{} k} = \frac{{S}_{ref} {E}_{ref} {ε}_{ref}^{{}_{} k}}{S} + E ( {ε}_{iso , e}^{{}_{} k} + {ε}_{pre , e}^{{}_{} k} ) + {v}_{in} & [ Formula 5 ]\end{matrix}$$

In Formula 5, the superscript k indicates a time step. Vin indicates a disturbance term of the internal stress. In Formula 5, as factors of a strain, an inherent strain due to isolation and an inherent strain due to the growth of precipitates are considered. Even if other factors are further present, the substantially equal processing can be applied by adding such other factors to the term of the sum of inherent strains.

In a case where formulas of two inherent strains, a formula of measured values acquired by the strain sensor S1, and a formula of an internal stress are expressed as equation of states, the following Formula 6 is obtained.

$$\\ \begin{matrix}{ε}_{iso , e}^{{}_{} k + 1} = {ε}_{iso , e}^{{}_{} k} + {k}_{iso , 0} + {k}_{iso , 1} {\vert I \vert}^{{α}_{iso , 1}} + {v}_{iso , e} & [ Formula 6 ]\end{matrix}$$

$$\\ {ε}_{pre , e}^{{}_{} k + 1} = {ε}_{pre , e}^{{}_{} k} + {k}_{pre , 0} ( {σ}_{in}^{{}_{} k} ) + {k}_{pre , 1} ( {σ}_{in}^{{}_{} k} ) {\vert I \vert}^{{α}_{pre , 1}} + {v}_{pre , e}$$

$$\\ {ε}_{ref}^{{}_{} k + 1} = {ε}_{ref}^{{}_{} k} + {v}_{ref}$$

$$\\ {σ}_{in}^{{}_{} k} = \frac{{S}_{ref} {E}_{ref} {ε}_{ref}^{{}_{} k}}{S} + E ( {ε}_{iso , e}^{{}_{} k} + {ε}_{pre , e}^{{}_{} k} ) + {v}_{in}$$

Formula 6 includes a formula of a strain generated on the side surface portion 312 besides the formula (Formula 2) expressing a progress speed of an inherent strain due to isolation, the formula (Formula 3) expressing a progress speed of the inherent strain due to the growth of the precipitates, and the formula (Formula 5) relating to an internal stress. In Formula 6, ϵ_{ref} indicates an observation amount. Also with respect to a current I, a value measured by the ammeter S4 may also be used. In Formula 6, an inherent strain is used as a quantity of state. However, a stress obtained by multiplying an inherent strain by the Young's modulus may be used as a quantity of state.

The equation of state expressed by Formula 6 can be transformed into an expression that uses vectors as expressed by Formula 7.

$$\\ \begin{matrix}{x}^{{}_{} k + 1} = f ( {x}^{{}_{} k} ) + {v}^{{}_{} k} & [ Formula 7 ]\end{matrix}$$

$$\\ {x}^{{}_{} k} = ( \begin{matrix}{ε}_{iso , e}^{{}_{} k} \\ {ε}_{pre , e}^{{}_{} k} \\ {ε}_{ref}^{{}_{} k} \\ {σ}_{in}^{{}_{} k}\end{matrix} ) {v}^{{}_{} k} = ( \begin{matrix}{v}_{iso , e}^{{}_{} k} \\ {v}_{pre , e}^{{}_{} k} \\ {v}_{ref}^{{}_{} k} \\ {v}_{in}^{{}_{} k}\end{matrix} )$$

In Formula 7, x^{k} is a vector (state vector) having a quantity of state as an element, and v^{k} is a vector (disturbance vector) having a quantity of disturbance as an element. f indicates a nonlinear transformation of the equation of state indicated in Formula 6. The disturbance term may be calculated by setting some or all elements of the disturbance term to 0.

In the embodiment 1, a strain in the energy storage device 2 is measured by the strain sensor S1, ϵ_{ref} is an observation quantity. An equation of observation is expressed by the following formula.

y^{k}=C_{T}x^{k} (8)

In this Formula 8, y^{k} is an observation value, and C^{T} is an observation vector. A disturbance vector may also be added to the equation of observation. In a case where ϵ_{ref} of the third component is taken out as an observation amount, the observation vector C^{T} is expressed as expressed in Formula 9.

C_{T}=(0 0 1 0) (9)

The estimation device 1 according to the embodiment 1 sequentially calculates updating of time of the simulation model expressed by the equation of state expressed by Formula 7 and the equation of observation expressed by Formula 8 using a nonlinear filter, and derives the time transition of an internal stress σᵢₙ.

Hereinafter, a method of sequentially calculating the updating of time using an ensemble Kalman filter as an example of the nonlinear filter will be described.

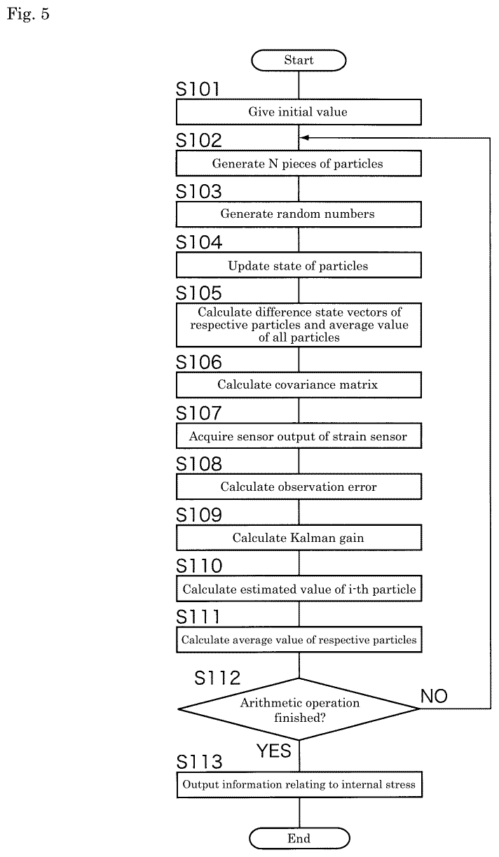

FIG. 5 is a flowchart for describing steps of estimating an internal stress in the embodiment 1. The arithmetic operation unit 11 of the estimation device 1 gives an initial value k where k=1 (step S101). It is sufficient for the arithmetic operation unit 11 to give a measured value of a strain measured in advance using the strain sensor S1 as an initial value of ϵ_{ref}^{k}, and to give temporary values set in advance as an initial value of an inherent strain ϵ_{iso, e}^{k} due to the isolation, as an inherent strain ϵ_{pre, e}^{k} caused by the growth of precipitates, and as an internal stress σᵢₙ^{k}.

Next, the arithmetic operation unit 11 generates N pieces of particles for each state variable (step S102). In this step, N is approximately 10² to 10⁶.

Next, the arithmetic operation unit 11 generates the random number corresponding to vₖ with respect to i, wherein i=1, 2, . . . , and N (step S103). It is assumed that vₖ follows the normal distribution, and the variance is known.

The arithmetic operation unit 11 performs an arithmetic operation based on Formula 10 with respect to all N pieces of particles and updates the state of the particles to the state of the particles at the next time step (step S104).

xₖ⁽ⁱ⁾=f(xₖ₋₁⁽ⁱ⁾)+vₖ⁽ⁱ⁾ (10)

The arithmetic operation unit 11 calculates a difference xₖ⁽ⁱ⁾_bar between the state vectors of the respective particles (i=1, 2, . . . , and N) and an average value of the state vectors of all particles (step S105). xₖ⁽ⁱ⁾_bar is expressed by Formula 11.

$$\\ \begin{matrix}\overline{{x}_{k}^{{}_{} ( i )}} = {x}_{k}^{{}_{} ( i )} - \frac{1}{N} {\sum }_{i = 1}^{N} {x}_{k}^{{}_{} ( i )} & [ Formula 11 ]\end{matrix}$$

The arithmetic operation unit 11 calculates a covariance matrix Pₖ of state quantity prediction values relating to all particles (step S106). The covariance matrix Pₖ is represented by Formula 12.

$$\\ \begin{matrix}{P}_{k} = \frac{1}{N - 1} {\sum }_{i = 1}^{N} \overline{{x}_{k}^{{}_{} ( i )}} \cdot {\overline{{x}_{k}^{{}_{} ( i )}}}^{{}_{} T} & [ Formula 12 ]\end{matrix}$$

The arithmetic operation unit 11 acquires a sensor output of the strain sensor S1 through the input unit 13 (step S107). The acquired sensor output of the strain sensor S1 gives an observation value yₖⁱ of each particle in the time step k.

The arithmetic operation unit 11 calculates an observation error rₖⁱ in the time step k of the i-th particle (step S108). In this processing, wₖ is an observation disturbance. The observation error rₖⁱ is expressed by Formula 13.

rₖⁱ=yₖⁱ−C^{T}xₖ⁽ⁱ⁾+wₖ (13)

The arithmetic operation unit 11 calculates a Kalman gain Kₖ in the time step k (step S109). The Kalman gain Kₖ is expressed by Formula 14.

Kₖ=PₖC(C^{T}PₖC+Qₖ)⁻¹ (14)

The arithmetic operation unit 11 calculates an estimated value xₖ⁽ⁱ⁾_hat of the i-th particle (step S110). The estimated value xₖ⁽ⁱ⁾_hat is expressed by Formula 15. That is, the arithmetic operation unit 11 corrects the first prediction value of Formula 10 using the observation error rₖⁱ of Formula 13 and the Kalman gain Kₖ of Formula 14.

[symbol]

=xₖ⁽ⁱ⁾+Kₖrₖ⁽ⁱ⁾ (15)

The arithmetic operation unit 11 calculates an average value xₖ_hat of each particle (step S111). The average value xₖ_hat of each particle expresses a state vector estimated value obtained by the ensemble Kalman filter, and is calculated by the following formula.

$$\\ \begin{matrix}= \frac{1}{N} {\sum }_{i = 1}^{N} & [ Formula 16 ]\end{matrix}$$

The estimated value (average value xₖ_hat of each particle) obtained by Formula 16 includes an estimated value of an internal stress σᵢₙ.

Next, the arithmetic operation unit 11 determines whether or not to end the arithmetic operation (step S112). For example, in a case where an end instruction is given from a user, the arithmetic operation unit 11 determines to finish the arithmetic operation. When the arithmetic operation unit 11 determines not to finish the arithmetic operation (S112: NO), the arithmetic operation unit 11 returns the processing to step S102 and performs the arithmetic operation at the next time step.

When the arithmetic operation unit 11 determines that the arithmetic operation is finished (S112: YES), the arithmetic operation unit 11 outputs information relating to the estimated internal stress Fin from the output unit 14 (step S113), and finishes the processing according to this flowchart. The information relating to the internal stress σᵢₙ that the arithmetic operation unit 11 outputs may be a value of the internal stress itself or may be a physical quantity derived based on the internal stress (for example, an internal resistance of the energy storage device 2). Further, the information relating to the internal stress σᵢₙ that the arithmetic operation unit 11 outputs may be a graph that indicates the time transition of the internal stress σᵢₙ, may be a two-dimensional or three-dimensional graph or a contour map that indicates the stress distribution.

As has been described above, the estimation device 1 estimates the internal stress Fin of the energy storage device 2 using an ensemble Kalman filter. The ensemble Kalman filter is a filter method that is intended to be used for a state space model having nonlinearity or non-Gaussivity, and can be used for a more general state space model. The ensemble Kalman filter has a relatively simple algorithm, and can be easily implemented in the estimation device 1.

The flowchart illustrated in FIG. 5 describes an arithmetic operation method using the ensemble Kalman filter. Alternatively, the estimation device 1 may estimate the internal stress in of the energy storage device 2 using a nonlinear filter such as a particle filter, an extended Kalman filter, or an unscented Kalman filter.

In the embodiment 1, in deriving Formula 5, the linearity between an inherent strain and an internal stress is taken into account. However, the relationship between the inherent strain and the internal stress may be nonlinear. Even in the case where the relationship between the inherent strain and the internal stress is nonlinear, the estimation device 1 can estimate the internal stress Gin of the energy storage device 2 by performing an arithmetic operation using a nonlinear filter.

### (Embodiment 2)

In the embodiment 2, the description will be made with respect to a method of estimating an internal stress by further taking into account an inherent strain attributed to a temperature.

The configuration of an estimation device 1 and the configuration of an energy storage device 2 are substantially equal to the corresponding configurations of the embodiment 1. Accordingly, the description of these configurations will be omitted.

In the embodiment 2, as factors that cause a strain in the energy storage device 2, (1) the isolation of active material particles, (2) the growth of precipitates, and (3) the thermal expansion are taken into account. The inherent strain caused by the isolation of active material particles and an inherent strain caused by the growth of precipitates are substantially equal to the corresponding inherent strains in the embodiment 1. Accordingly, the description of these inherent strains is omitted.

### (3) Inherent Strain Due to Thermal Expansion

The thermal expansion is a phenomenon where a volume of the energy storage device 2 is increased as the temperature is increased. The thermal expansion is irrelevant to the deterioration of the energy storage device 2, and is determined based on only a temperature at a certain moment. In the embodiment 2, a model is described where it is assumed that the thermal expansion is proportional to a temperature, and an inherent strain corresponding to the difference in temperature from the reference temperature is generated.

An inherent strain due to a temperature is expressed by the following Formula 17, for example.

ϵ_{th,0}^{k}=αₜₕ^{k}(T^{k}−T_{ref})+v_{th,e} (17)

In Formula 17, ϵ_{th, 0} indicates an inherent strain due to thermal expansion. αₜₕ indicates a linear thermal expansion coefficient. T indicates a temperature at a certain point of time, and T_{ref} indicates a reference temperature. V_{th, e} indicates an external disturbance term of thermal expansion. In Formula 17, a superscript k indicates a time step. A subscript th indicates a temperature (thermal). Measurement data of a temperature sensor S2 is used as the temperature T, and measurement data of a temperature sensor S3 is used as the reference temperature T_{ref}. The equation of state including a temperature is expressed by the following Formula 18.

$$\\ \begin{matrix}{ε}_{iso , e}^{{}_{} k + 1} = {ε}_{iso , e}^{{}_{} k} + {k}_{iso , 0} ( {T}^{{}_{} k} ) + {k}_{iso , 1} ( {T}^{{}_{} k} ) {\vert I \vert}^{{α}_{iso , 1}} + {v}_{iso , e} & [ Formula 18 ]\end{matrix}$$

$$\\ {ε}_{pre , e}^{{}_{} k + 1} = {ε}_{pre , e}^{{}_{} k} + {k}_{pre , 0} ( {T}^{{}_{} k} , {σ}_{in}^{{}_{} k} ) + {k}_{pre , 1} ( {T}^{{}_{} k} , {σ}_{in}^{{}_{} k} ) {\vert I \vert}^{{α}_{pre , 1}} + {v}_{pre , e}$$

$$\\ {ε}_{th , e}^{{}_{} k} = {α}_{th}^{{}_{} k} ( {T}^{{}_{} k} - {T}_{ref} ) + {v}_{th , e}$$

$$\\ {ε}_{ref}^{{}_{} k + 1} = {ε}_{ref}^{{}_{} k} + {v}_{ref}$$

$$\\ {σ}_{in}^{{}_{} k} = \frac{{S}_{ref} {E}_{ref} {ε}_{ref}^{{}_{} k}}{S} + E ( {ε}_{iso , e}^{{}_{} k} + {ε}_{th , e}^{{}_{} k} + {ε}_{pre , e}^{{}_{} k} ) + {v}_{in}$$

In the embodiment 2, rate coefficients k_{iso, 0,} k_{iso, 1} that indicate a progress speed of an inherent strain due to isolation are used as functions of the temperature T. As the functional form, a monotonically increasing function of the temperature T is used. As the monotonically increasing function, for example, an Arrhenius type function that indicates a feature where a progress speed of isolation is increased as the temperature is increased is used. In the embodiment 2, the rate coefficients k_{pre, 0}, k_{pre, 1} that indicate the progress speeds of an inherent strain due to the growth of the precipitates are functions of the temperature T and the internal stress σᵢₙ. As the functional form, a monotonically decreasing function of the temperature T is used. As the monotonically decreasing function, for example, a function that indicates a feature where a progress speed of precipitates is increased as the temperature is increased is used. To a fifth equation in Formula 18, a term relating to an inherent strain ϵ_{th, e}^{k} due to thermal expansion is added.

The equation of state expressed by Formula 18 can be transformed into an expression that uses vectors as expressed by Formula 19.

$$\\ \begin{matrix}{x}^{{}_{} k + 1} = f ( {x}^{{}_{} k} ) + {v}^{{}_{} k} & [ Formula 19 ]\end{matrix}$$

$$\\ {x}^{{}_{} k} = ( \begin{matrix}{ε}_{iso , e}^{{}_{} k} \\ \begin{matrix}{ε}_{pre , e}^{{}_{} k} \\ {ε}_{th , e}^{{}_{} k}\end{matrix} \\ {ε}_{ref}^{{}_{} k} \\ {σ}_{in}^{{}_{} k}\end{matrix} ) {v}^{{}_{} k} = ( \begin{matrix}{v}_{iso , e}^{{}_{} k} \\ \begin{matrix}{v}_{pre , e}^{{}_{} k} \\ {v}_{th , e}^{{}_{} k}\end{matrix} \\ {v}_{ref}^{{}_{} k} \\ {σ}_{in}^{{}_{} k}\end{matrix} )$$

In the embodiment 2, the equation of observation is substantially equal to Formula 8 described in the embodiment 1. However, in the embodiment 2, since a strain and a temperature of the energy storage device 2 are extracted as observation amounts and hence, the observation vector CT is expressed as Formula 20.

C_{T}=(0 0 1 1 0) (20)

The estimation device 1 according to the embodiment 2 sequentially calculates updating of time of the simulation model (time-series model) expressed by the equation of state expressed in Formula 19 and the equation of observation expressed in Formula 8 using a nonlinear filter, and derives the time transition of an internal stress σᵢₙ that takes into account a temperature. The arithmetic operation method used in the embodiment 2 is substantially equal to the arithmetic operation method used in the embodiment 1. The estimation device 1 estimates an internal stress σᵢₙ in the energy storage device 2 by performing an arithmetic operation according to the steps in the flowchart illustrated in FIG. 5.

The estimation device 1 according to the embodiment 1 and the estimation device 1 according to the embodiment 2 are configured to estimate an internal stress in the energy storage device 2 by performing the estimation program PG1. Alternatively, by cooperatively using an estimation program for estimating the deterioration of the energy storage device 2 together with the estimation program, the estimation device 1 may simultaneously simulate a mode where the electrochemical specification deteriorates along with the use of the energy storage device 2 and a mode where the energy storage device 2 expands. As an estimation program for estimating the deterioration of the energy storage device 2, for example, a method described in JP-A-2020-48369 is used.

In the embodiment 2, an inherent strain of the energy storage device 2 caused by the thermal expansion is taken into account. Alternatively, an inherent strain due to expansion and shrinkage associated with insertion and extraction of the active material particles may be taken into account. Such expansion and shrinkage occur when active material particles are inserted into or extracted from a positive electrode and a negative electrode during normal charging and discharging irrelevant to the deterioration of the energy storage device 2. The inherent strain due to insertion and extraction of the active material particles is reversible, and is expressed, for example, as a function of SOC (State Of Charge).

In the embodiment 2, a model that takes into account the influence of a temperature through a thermal stress is described. Alternatively, only the temperature dependence of the rate coefficient of isolation or the growth of precipitates may be taken into account without taking into account an inherent strain due to thermal expansion. In this case, the third equation in Formula 18 and Formula 19 may be excluded.

### (Embodiment 3)

In the embodiment 3, the description is made with respect to the configuration where a value of an internal stress σᵢₙ estimated by the estimation device 1 is used in estimating an electrochemical phenomenon of the energy storage device 2.

The configuration of an estimation device 1 and the configuration of an energy storage device 2 are substantially equal to the corresponding configurations of the embodiment 1. Accordingly, the description of these configurations will be omitted.

The electrochemical phenomenon of the energy storage device 2 is described by a physical model such as a Newman model or a Randle model. The equation of observation is expressed by Formula 21, for example.

V=OCPₚ(c_{p,1})−OCPₙ(c_{n,1})−Rₒₕₘ(σᵢₙ)I−η_{act,p}(c_{p,1}, T, T)−η_{act,p}(c_{p,1}, I, T) (21)

In Formula 21, V indicates a terminal voltage of the energy storage device 2, and is an observation value observed by a voltmeter S5. OCPₚ (c_{p, 1}) is an equilibrium potential of a positive electrode, and is a function of the occluded lithium ion concentration c_{p, 1} at an interface of positive active material particles. OCPₙ (c_{n, 1}) is an equilibrium potential of a negative electrode, and is a function of the occluded lithium ion concentration c_{n, 1} at an interface of negative active material particles. Rₒₕₘ (σᵢₙ) indicates an ohmic resistance (an internal resistance) of the energy storage device 2. Rₒₕₘ (σᵢₙ) indicates that the ohmic resistance is a function of the internal stress σᵢₙ. As the value of the internal stress σᵢₙ, a value estimated by the estimation device 1 is used. Rₒₕₘ (σᵢₙ) may be a function of a temperature T. I indicates a current flowing through the energy storage device 2. That is, the term of Rₒₕₘ (σᵢₙ) I indicates a voltage drop due to an ohmic resistance. η_{act, p} (c_{p, 1}, I) is an activation overvoltage at the interface of the positive active material particles, and is a nonlinear function of an occluded lithium ion concentration c_{p, 1}, a current I, and a temperature T at the interface of the positive active material particles. η_{act, n} (c_{n, 1}, I) is an activation overvoltage at the interface of the negative active material particles, and is a nonlinear function of an occluded lithium ion concentration c_{n, 1}, a current I, and a temperature T at the interface of the negative active material particles. That is, a voltage V of an observation value is a complicated nonlinear function of an occluded lithium ion concentration c_{p, 1} at the interface of the positive active material particles, an occluded lithium ion concentration c_{n, 1} at the interface of the negative active material particles, a current I, and a temperature T.

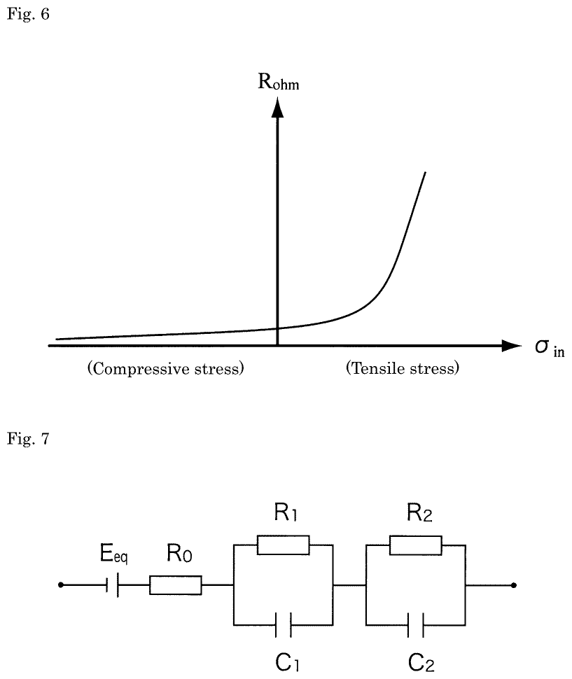

FIG. 6 is a graph illustrating a relationship between an internal stress σᵢₙ and an ohmic resistance Rₒₕₘ of the energy storage device 2. The internal stress σᵢₙ of the energy storage device 2 is taken on an axis of abscissas and, an ohmic resistance Rₒₕₘ of the energy storage device 2 is taken on an axis of ordinates. As illustrated in the graph in FIG. 6, in consideration of the experimental fact that the higher a compressive stress, the lower the ohmic resistance becomes, the functional form of Rₒₕₘ is determined such that a relationship ∂Rₒₕₘ/∂σᵢₙ≥0 is satisfied. The storage unit 12 of the estimation device 1 may store a function for converting the internal stress σᵢₙ into the ohmic resistance Rₒₕₘ, or may store a conversion table for converting the internal stress σᵢₙ into the ohmic resistance Rₒₕₘ.

The estimation device 1 converts a value of the internal stress σᵢₙ estimated using the above-described method into a value of the ohmic resistance Rₒₕₘ in accordance with a predetermined function (or table). The estimation device 1 estimates physical quantities including equilibrium potentials of the positive electrode and the negative electrode and an activation overvoltage by performing the state estimation based on Formula 21 using a value of the ohmic resistance Rₒₕₘ obtained after the conversion. As the estimation method, for example, a method described in JP-A-2020-160971 is used.

In the all-solid-state battery, a contact area between the solid electrolyte and the active material particles changes corresponding to a binding force or an internal stress, and battery characteristics largely change corresponding to the change in the contact area. In the embodiment 3, an electrochemical phenomenon is estimated using an estimation result of an internal stress Fin. Accordingly, it is possible to accurately estimate an electrochemical phenomenon of an all-solid-state battery where there is a possibility that battery characteristics are greatly changed corresponding to an internal stress.

It has been known that, in a battery having a negative electrode that is formed using metal lithium, an internal resistance such as an ohmic resistance and a growth rate of precipitates change corresponding to an internal stress.

### (Embodiment 4)

In an embodiment 4, the description is made with respect to the configuration where an electrochemical phenomenon is estimated using an equivalent circuit model of an energy storage device 2.

The configuration of an estimation device 1 and the configuration of an energy storage device 2 are substantially equal to the corresponding configurations of the embodiment 1. Accordingly, the description of these configurations will be omitted.

FIG. 7 is a circuit diagram illustrating an example of an equivalent circuit model. In many cases, the equivalent circuit model of the energy storage device 2 is expressed as a combination of a resistor, a capacitance component and a voltage source as illustrated in FIG. 7, for example.

In FIG. 7, R₀ indicates an ohmic resistance component, R₁ indicates a reaction resistance component of a positive electrode, C₁ indicates a capacitance component of a positive electrode, R₂indicates a reaction resistance component of a negative electrode, C₂ indicates a capacitance component of a negative electrode, and E_{eq} indicates an open circuit voltage (OCV). However, the equivalent circuit model illustrated in FIG. 7 is provided as an example, and there is no limitation on the type of the combination, that is, the combination in series or in parallel, the number and type of electric circuit elements.

It is known that the charging and discharging characteristics of the energy storage device 2 are affected by a temperature and an SOC. Assume that an open circuit voltage (OCV) is a function of an SOC, and R₀ to R₂ and C₁ and C₂ are functions of a temperature. Under such conditions, an equation of observation is expressed by Formula 22.

y_{U}^{k}=V=OCV(SOC)+C_{T}x_{U}^{k}+R₀(σᵢₙ)u^{k} (22)

Here, y_{U} is an observation value. In the embodiment 4, y_{U} indicates a terminal voltage V of the energy storage device 2. The superscript k indicates a time step. The OCV (SOC) indicates an open circuit voltage and is expressed as a nonlinear function of the SOC. C^{T} indicates an observation vector, and x_{U} indicates a state vector. R₀ (σᵢₙ) indicates an ohmic resistance and is expressed as a function of the internal stress σᵢₙ. The functional form of R₀ is determined such that a relationship ∂R₀/∂σᵢₙ≥0 is satisfied. A storage unit 12 of the estimation device 1 may store a function for converting the internal stress σᵢₙ into the ohmic resistance R₀, or may store a conversion table for converting the internal stress σᵢₙ into the ohmic resistance R₀. u indicates a current flowing through the energy storage device 2.

The estimation device 1 converts a value of the internal stress σᵢₙ estimated using the above-described method into a value of the ohmic resistance R₀ in accordance with a predetermined function (or table). The estimation device 1 estimates physical quantities including an open circuit voltage OCV by performing the state estimation based on Formula 22 using a value of the ohmic resistance R₀ obtained after the conversion. As the estimation method, for example, a method described in JP-A-2020-160971 is used.

In the all-solid-state battery, a contact area between the solid electrolyte and the active material particles changes corresponding to a binding force or an internal stress, and battery characteristics largely change corresponding to the change in the contact area. In the embodiment 4, an electrochemical phenomenon is estimated using an estimation result of an internal stress σᵢₙ. Accordingly, it is possible to accurately estimate an electrochemical phenomenon of an all-solid-state battery where there is a possibility that battery characteristics are greatly changed corresponding to an internal stress.

### (Embodiment 5)

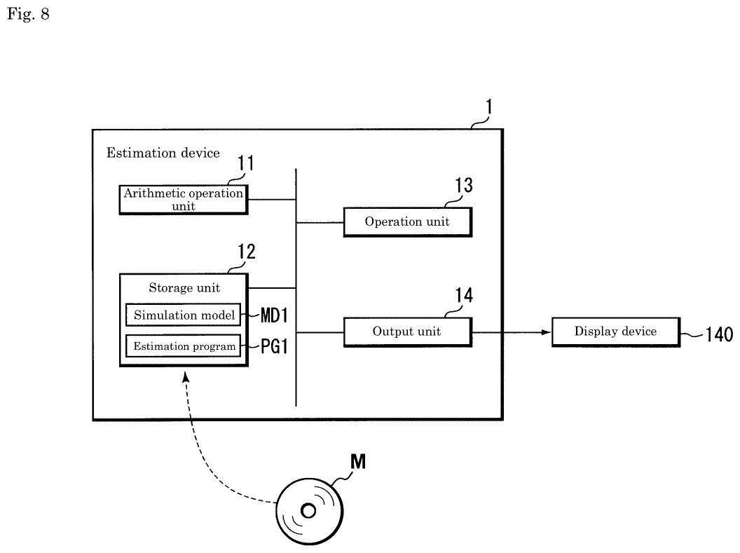

FIG. 8 is a block diagram illustrating the internal configuration of an estimation device 1 according to an embodiment 5. The estimation device 1 includes an operation unit 15 besides the arithmetic operation unit (estimation unit) 11, a storage unit 12, and an output unit 14 described above. The operation unit 15 includes an interface for connecting the estimation device 1 with various operation devices. The operation device is a device for receiving a user's operation, such as an operation of a keyboard, an operation of a mouse, or an operation of a touch panel. The operation unit 15 outputs operation information received through the operation device to the arithmetic operation unit 11. The arithmetic operation unit 11, the storage unit 12, and the output unit 14 have substantially the same configuration as the corresponding units of the embodiment 1 and hence, the description of these units will be omitted.

The estimation device 1 according to the embodiment 5 estimates an electrochemical phenomenon of the energy storage device 2 based on information set in advance or information inputted through the operation unit 15. The energy storage device 2 that is a simulation target according to the embodiment 5 is an all-solid-state battery.

In a conventional electrolyte solution-based lithium ion battery, a surrounding of each of active material particles is filled with an electrolyte solution, and the active material particles are in a state where the entire surface of the active material particle is in contact with the electrolyte solution. In this case, an apparent diffusion coefficient (an effective diffusion coefficient) and ionic conductivity (effective ionic conductivity) agrees with a true diffusion coefficient and true ionic conductivity.

On the other hand, in an all-solid-state battery, ions are exchanged only through a minute area where active material particles and a solid electrolyte are brought into contact with each other. Accordingly, it is predicted that the apparent diffusion coefficient (the effective diffusion coefficient) and the ionic conductivity (effective ionic conductivity) are smaller than the true diffusion coefficient and the true ion conductivity. However, at present, there has been no verification example with respect to the relationship between a contact area between active material particles and a solid electrolyte and an effective diffusion coefficient or effective ionic conductivity.

The inventors of the present application have found the relationship between the contact area between the active material particles and the solid electrolyte and the effective diffusion coefficient and the effective ionic conductivity by numerical value arithmetic operation (simulation). In the embodiment 5, a simulation method that estimates an electrochemical phenomenon of the energy storage device 2 using these relationships is proposed. That is, the electrochemical phenomenon of the energy storage device 2 is estimated based on a contact area between the active material particles and the solid electrolyte (or an internal stress of the energy storage device 2).

Hereinafter, as a reference example, with respect to an electrolyte solution-based lithium ion battery, an arithmetic operation method for obtaining an effective diffusion coefficient of an electrolyte solution will be described.

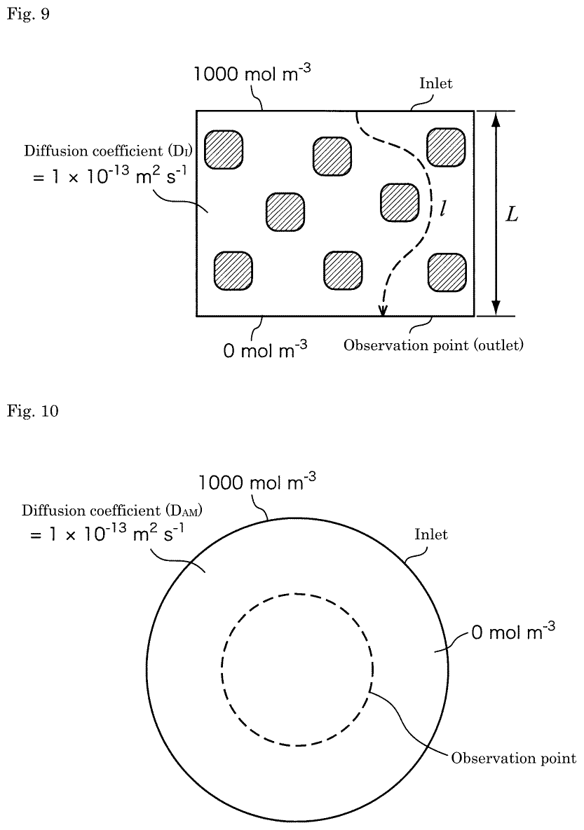

FIG. 9 is an explanatory view for describing a method of calculating an effective diffusion coefficient. FIG. 9 shows a mode where a positive electrode of an electrolyte solution-based lithium ion battery is simplified. FIG. 9 illustrates a state where a plurality of active material particles are present inside a positive electrode, and the inside and the periphery of the active material particles are filled with an electrolyte solution. Assuming a thickness of the positive electrode as L (m) and a length of a conduction path indicated by a broken line in the drawing as l (m), a bending degree τ due to gaps and active material particles is described as τ=l/L. In this case, the relationship between an effective diffusion coefficients D_{1, eff} (m₂s⁻¹) and a true diffusion coefficient D₁ (m²s⁻¹) is expressed by the following formula. ϵ indicates a volume occupancy of the electrolyte solution.

$$\\ \begin{matrix}{D}_{l , eff} = \frac{ε}{τ} {D}_{l} & [ Formula 23 ]\end{matrix}$$

In the same manner, the relationship between the effective ionic conductivity σ_{1, eff} (Sm⁻¹) and a true ionic conductivity σ₁ (Sm⁻¹) of the electrolyte solution is expressed by the following formula.

$$\\ \begin{matrix}{σ}_{l , eff} = \frac{ε}{τ} {σ}_{l} & [ Formula 24 ]\end{matrix}$$

With respect to the model illustrated in FIG. 9, by assuming an upper side of the model as an inlet of the electrolyte solution and a lower side of the model as an outlet (an observation point), and by giving an appropriate boundary condition to the model, a flow rate of the electrolyte solution at the observation point can be calculated. As the boundary condition, for example, the concentration of the electrolyte solution at the inlet (for example, 1000 mol m⁻³) and the concentration of the electrolyte solution at the outlet (for example, 0 mol m⁻³) are given.

Assuming the flow rate of the electrolyte solution at the observation point as J₁ and the concentration of the electrolyte solution at the observation point as C₁ as c1, the relationship between the flow rate J₁ and the concentration c₁ is expressed by the following formula. D_{1, eff} indicates an effective diffusion coefficient. The effective diffusion coefficient D_{1, eff} of the electrolyte solution is calculated based on Formula 25.

J=−_{1,eff}∇c₁ (25)

In the all-solid-state battery, some of the active material particles are brought into contact with the solid electrolyte, and the inside and the periphery of the active material particles are not filled with the electrolyte. Therefore, the calculation method of an effective diffusion coefficient in the electrolyte solution-based lithium ion battery cannot be directly applied to the all-solid-state battery. In view of the above-mentioned circumstances, the inventors of the present application propose a method of introducing a concept of a contact area between active material particles and a solid electrolyte, and calculating an effective diffusion coefficient that changes corresponding to the contact area by simulation.

FIG. 10 is an explanatory view illustrating a method of calculating an effective diffusion coefficient in an all-solid-state battery. In the embodiment 5, it is assumed that the active material particles in the all-solid-state battery are spherical bodies. The arithmetic operation unit 11 of the estimation device 1 sets a spherical body surface of the spherical body as an inlet and sets a surface of a concentric sphere disposed inside the spherical body as an observation point, and calculates a flow rate J_{AM} (mol m⁻²s⁻¹) at the observation point when a boundary state is given. The observation point is set, for example, as the surface of the concentric sphere having a radius that is half of a radius of the spherical body. As the boundary condition, a concentration of, for example, 1000 mol m⁻³ is given around the spherical body, and a concentration of, for example, 0 mol m⁻³ is given inside the spherical body. The relationship between the flow rate JAM and an effective diffusion coefficient D_{AM, eff} is expressed by Formula 26. In Formula 26, c_{AM} is the concentration of the active material. The arithmetic operation unit 11 substitutes the calculated flow rate J_{AM} into Formula 26 to calculate the effective diffusion coefficient D_{AM, eff} of the active material.

J_{AM}=−D_{AM,eff}∇c_{AM} (26)

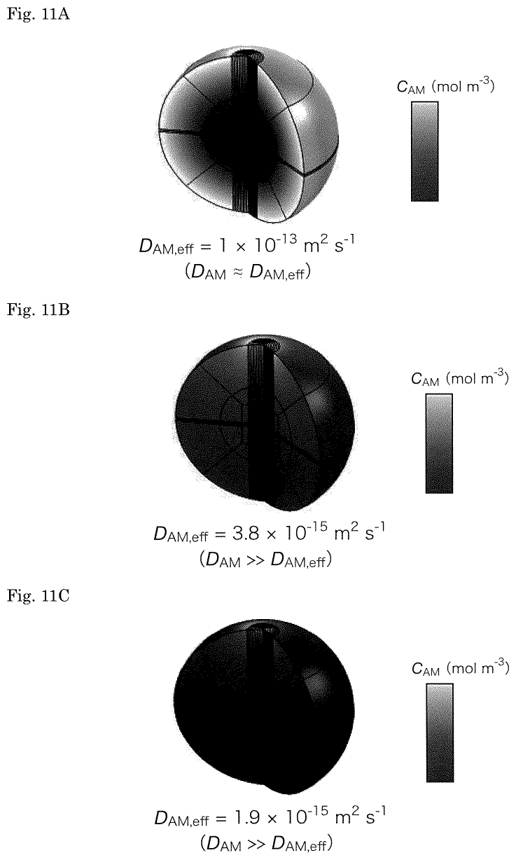

FIG. 11A to FIG. 11C are views illustrating the calculation results of effective diffusion coefficients in the all-solid-state battery. FIG. 11A illustrates a spherical body that is formed by rotating an active material about a rotation axis in order to express an active material of an all-solid-state battery that is assumed as a spherical body. FIG. 11A illustrates a calculation result in a case where the entire surface of the spherical body is brought into contact with an electrolyte. In the case where the entire surface of the spherical body is brought into contact with the electrolyte, the uniform inflow is generated at the observation point. Accordingly, it is estimated that a diffusion coefficient of the active material and an effective diffusion coefficient of the active material become equal. As a result of actual calculation, the effective diffusion coefficient D_{AM}. eff was 1.0×10⁻¹³ (m² s⁻¹). Accordingly, the effective diffusion coefficient D_{AM} had the same value as the diffusion coefficient D_{AM, eff} of the active material. As a result, the validity of the calculation method was proved.

FIG. 11B illustrates a calculation result in a case where, in a spherical crown cut out by a cone formed by rotating an active material at a half vertex angle of 10 degrees with respect to a symmetry axis that passes through the center of a sphere, a surface area that is included in a spherical surface of the spherical crown is in contact with an electrolyte. In the case where the half vertex angle is 10 degrees, the effective diffusion coefficient D_{AM, eff} was 3.8×10⁻¹⁵ (m²s⁻¹). Accordingly, the effective diffusion coefficient D_{AM, eff} became a value smaller than the diffusion coefficient D_{AM} of the active material by approximately two digits.

FIG. 11 C illustrates a calculation result in the case where the above-mentioned half vertex angle is 5 degrees. In the case where the half vertex angle is 5 degrees, the effective diffusion coefficient D_{AM, eff} was 1.9×10⁻¹⁵ (m²s⁻¹). Accordingly, in this case, the effective diffusion coefficient D_{AM, eff} became a value further smaller than the effective diffusion coefficient D_{AM, eff} in the case where the half vertex angle is 10 degrees.

FIG. 12 is a graph illustrating a relationship between a contact area ratio and an effective diffusion coefficient. Both an axis of abscissas and an axis of ordinates in the graph illustrated in FIG. 12 are logarithmic axes. The contact area ratio is taken on the axis of abscissas, and the effective diffusion coefficient (m²/s) is taken on the axis of ordinates. The contact area ratio is a ratio of an area of a spherical crown included in a surface of a sphere to a surface area of the sphere. The contact area ratio is a parameter that indicates the degree of contact between an active material and a solid electrolyte. The contact area is obtained by multiplying the contact area ratio taken on the axis of abscissas by the surface area of the sphere that assumes the active material. From the logarithmic axes plots illustrated in FIG. 12, it is understood that the relationship between the contact area and the effective diffusion coefficient is formulated by Formula 27. The contact area can be estimated by analyzing an X-ray CT image or the like in actual practice, and parameters that affect the contact area can also be used. For example, in the case of an electrode obtained by press molding, a value such as a residual porosity of the electrode mixture may be used.

D_{AM,eff}=−αexp(−bx)+c (27)

In Formula 27, D_{AM, eff} indicates an effective diffusion coefficient, and x indicates a contact area. a, b, and c are coefficients. The coefficients a, b, and c are calculated by obtaining an approximate curve (a straight line in the logarithmic plots illustrated in FIG. 12) that passes through respective points on the graph. The approximate curve is obtained using a known method such as a least squares method.

The arithmetic operation unit 11 may calculate the effective ionic conductivity σ_{AM, eff} based on the value of the calculated effective diffusion coefficient D_{AM, eff}. According to the Einstein relationship expression, the relationship between the ionic conductivity σ and the diffusion coefficient D is expressed by Formula 28.

$$\\ \begin{matrix}σ = \frac{\vert z \vert {F}^{{}_{} 2} Dc}{RT} & [ Formula 28 ]\end{matrix}$$

In Formula 28, σ indicates ionic conductivity (S m⁻¹), z indicates an ionic charge (dimensionless), F indicates a Faraday constant (C mol⁻¹), D indicates a diffusion coefficient (m² s⁻¹), c indicates a lithium concentration (mol m⁻³), R indicates a gas constant (m² kg s⁻¹ K⁻¹ mol⁻¹), and T indicates a temperature (K).

The arithmetic operation unit 11 can calculate the effective ionic conductivity σ_{AM, eff} by substituting the value of the effective diffusion coefficient D_{AM, eff} calculated from the contact area into the diffusion coefficient D of Formula 28. The effective ionic conductivity σ_{AM, eff} is a physical quantity that affects the electric resistance of the energy storage device 2. That is, the estimation device 1 can estimate an electrochemical phenomenon in the energy storage device 2 based on a contact area between active material particles and a solid electrolyte in an all-solid-state battery.

Hereinafter, steps of performing an arithmetic operation that the estimation device 1 performs is described.

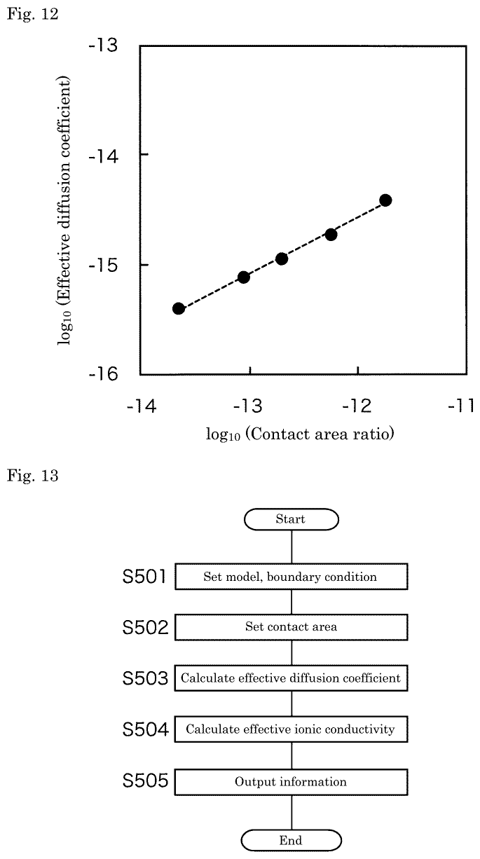

FIG. 13 is a flowchart illustrating the steps of performing arithmetic processing that the estimation device 1 according to embodiment 5 performs. The arithmetic operation unit 11 of the estimation device 1 sets, as a model of the all-solid-state battery, model where spherical active material particles and a solid electrolyte are brought into contact with each other, and gives a boundary condition (step S501). The model and the boundary condition of the all-solid-state battery may be set in advance, and may be stored in the storage unit 12. In this case, the arithmetic operation unit 11 may read a model and a boundary condition set in advance from the storage unit 12. Alternatively, the arithmetic operation unit 11 may receive the setting of a model and a boundary condition through the operation unit 15.

Next, the arithmetic operation unit 11 receives the setting of a contact area (a half vertex angle) (step S502). The contact area may be set by estimating an internal stress in the energy storage device 2. An actual value obtained by analyzing a scanning electron microscope (SEM) image of the energy storage device 2 may be given. A value of the contact area used for the simulation may be stored in advance in the storage unit 12, or may be given through the operation unit 15 at the time of performing calculation.

Next, the arithmetic operation unit 11 calculates an effective diffusion coefficient by calculating a flow rate at which an electrolyte flows into the observation point from the surface portion of the spherical body having the contact area set in step S502 (step S503). The relationship between the flow rate and the effective diffusion coefficient is expressed by Formula 26, and the effective diffusion coefficient is calculated as a coefficient of a concentration gradient.

Next, the arithmetic operation unit 11 calculates effective ionic conductivity by using the effective diffusion coefficient calculated in step S503 (step S504). The relationship between the effective diffusion coefficient and the effective ionic conductivity is expressed by Formula 28.

In the flowchart shown in FIG. 13, the arithmetic operation unit 11 is configured to calculate both the effective diffusion coefficient and the effective ionic conductivity. However, the arithmetic operation unit 11 may be configured to calculate only one of the effective diffusion coefficient and the effective ionic conductivity.

The arithmetic operation unit 11 may estimate other physical quantities relating to an electrochemical phenomenon of the energy storage device 2 based on the calculated effective diffusion coefficient or the calculated effective ionic conductivity. For example, in general, there exists a relationship of Rₒₕₘ=L/(σ×A) between conductivity σ (Sm⁻¹) and the internal resistance Rₒₕₘ (Ω), where L indicates a length (m) and A indicates a cross-sectional area (m²). Accordingly, the arithmetic operation unit 11 may estimate an internal resistance of the energy storage device 2 using this relationship formula.

Next, the arithmetic operation unit 11 outputs information relating to the calculated effective diffusion coefficient and the calculated effective ionic conductivity from the output unit 14 (step S505). The arithmetic operation unit 11 may output values of the calculated effective diffusion coefficient and the effective ionic conductivity, and may output numerical value ranges of these values. Alternatively, the arithmetic operation unit 11 may output a graph where the effective diffusion coefficients and the effective ionic conductivities with respect to the contact area are plotted.

As has been described above, the estimation device 1 according to the embodiment 5 can estimate physical quantities relating to the electrochemistry of the energy storage device 2 such as the effective diffusion coefficient and the effective ionic conductivity while taking into account the contact area between the active material particles and the solid electrolyte.

### (Embodiment 6)

In the embodiment 6, the configuration is described where an effective diffusion coefficient and an effective ionic conductivity are calculated based on an internal stress in an energy storage device 2.

In the embodiment 5, the description has been made with respect to the relationship between the contact area between the active material particles and the solid electrolyte and the effective diffusion coefficient or the effective ionic conductivity. For example, Formula 26 expresses the relationship between the contact area x and the effective diffusion coefficient D_{AM, eff}. However, in Formula 26, a compressive stress may be used in place of the contact area. The stress is a resistance force generated inside a member against a load, and is a force per unit area obtained by dividing the load by an area of the member. With respect to a stress applied to a portion where spherical elastic bodies are brought into contact with each other, the Hertz theory is adopted. According to the Hertz theory, a compressive force generated at the contact portion is expressed by Formula 29.

$$\\ \begin{matrix}{s}_{p} = \frac{3 F}{2 π {r}^{{}_{} 2}} & [ Formula 29 ]\end{matrix}$$

In formula, Sₚ indicates a compressive stress (Pa), F indicates a load (N), r indicates a radius (m) of a contact surface. By rewriting Formula 27 using Formula 29, the relationship between the effective diffusion coefficients D_{AM, eff} and a compressive stress Sₚ is obtained. The arithmetic operation unit 11 of the estimation device 1 may calculate the effective diffusion coefficient D_{AM, eff} of the active material particles by giving the compressive stress Sₚ in place of the contact area x.

Further, the arithmetic operation unit 11 may calculate the effective ionic conductivity σ_{AM, eff} by substituting the calculated effective diffusion coefficient D_{AM, eff} into Formula 28.

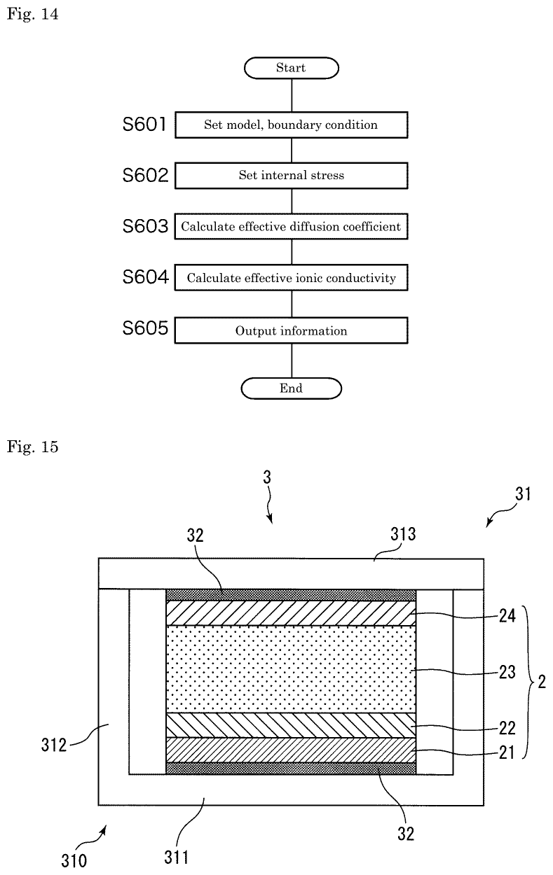

FIG. 14 is a flowchart for describing performance steps of arithmetic operation processing that the estimation device 1 according to the embodiment 6 performs. The arithmetic operation unit 11 of the estimation device 1, as a model of an all-solid-state battery, a model where active material particles each formed of a spherical body and a solid electrolyte are brought into contact with each other, is set, and a boundary condition is given (step S601). The model and the boundary condition of the all-solid-state battery may be set in advance, and may be stored in the storage unit 12. In this case, the arithmetic operation unit 11 may read a model and a boundary condition set in advance from the storage unit 12. Alternatively, the arithmetic operation unit 11 may receive the setting of a model and a boundary condition through the operation unit 15.

Next, the arithmetic operation unit 11 receives setting of an internal stress (step S602). A value of an internal stress used in simulation maybe stored in the storage unit 12 in advance, or may be given through the operation unit 15 at the time of performing calculation.

Next, the arithmetic operation unit 11 calculates an effective diffusion coefficient by calculating a flow rate at which an electrolyte flows into the observation point from a contact portion between the active material particles and the solid electrolyte (step S603). The relationship between the flow rate and the effective diffusion coefficient is expressed by Formula 26. The arithmetic operation unit 11 can calculate the effective diffusion coefficient as a coefficient of a concentration gradient based on Formula 26.

Next, the arithmetic operation unit 11 calculates effective ionic conductivity by using the effective diffusion coefficient calculated in S603 (step S604). The relationship between the effective diffusion coefficient and the effective ionic conductivity is expressed by Formula 28. The arithmetic operation unit 11 can calculate the effective ionic conductivity based on Formula 28.

Next, the arithmetic operation unit 11 outputs information relating to the calculated effective diffusion coefficient and the calculated effective ionic conductivity from the output unit 14 (step S605). The arithmetic operation unit 11 may output values of the calculated effective diffusion coefficient and the effective ionic conductivity, and may output numerical value ranges of these values. Alternatively, the arithmetic operation unit 11 may output a graph where the effective diffusion coefficients and the effective ionic conductivities with respect to the contact area are plotted.

In the flowchart illustrated in FIG. 14, the arithmetic operation unit 11 adopts the configuration where the arithmetic operation unit 11 calculates both the effective diffusion coefficient and the effective ionic conductivity. However, the arithmetic operation unit 11 may adopt the configuration where the arithmetic operation unit 11 calculates only one of the effective diffusion coefficient and the effective ionic conductivity.

Alternatively, the arithmetic operation unit 11 may estimate an internal resistance based on an internal stress in the energy storage device 2 by using a method substantially equal to the corresponding method described in the embodiment 3.

As has been described above, the estimation device 1 according to the embodiment 6 can estimate physical quantities relating to the electrochemistry of the energy storage device 2 such as the effective diffusion coefficient and the effective ionic conductivity by taking into account an internal stress in the energy storage device 2.

### (Embodiment 7)

Hereinafter, an energy storage device 2 which is a simulation target of the embodiment 7 will be described.

FIG. 15 is an explanatory view for describing the configuration of the energy storage device 2. The energy storage device 2 is a metal lithium battery, for example. The energy storage device 2 includes a stacked body formed of a positive electrode current collector layer 21, a positive active material layer 22, an electrolyte layer 23, and a negative electrode current collector layer 24.

The positive electrode current collector layer 21 is formed in the form of a metal foil, a metal mesh or the like. Metal used for forming the positive electrode current collector layer 21 is a metal having good conductivity such as aluminum, nickel, titanium, or stainless steel. A coating layer for adjusting a contact resistance may be formed on a surface of the positive electrode current collector layer 21. An example of the coating layer is a carbon coating.

The positive active material layer 22 is formed of a lithium-containing compound capable of occluding and releasing lithium ions. As the lithium-containing compound, for example, Lix CoO₂, LiₓNiO₂, LiₓMn₂O₄, LiₓFePO₄, or the like is used. The positive active material layer 22 may include a solid electrolyte, a conductivity aid, and a binder besides the positive active material.

The electrolyte layer 23 is a separator in which an electrolyte solution is impregnated. The electrolyte solution contains, for example, a nonaqueous solvent and a lithium salt dissolved in the nonaqueous solvent. As examples of a nonaqueous solvent, a cyclic carbonate ester solvent, a cyclic ether solvent, a chain ether solvent, a cyclic ester solvent, a chain ester solvent and the like are named. As examples of lithium salt, LiPF₆, LiBF₄, LIN (SO₂CF₃)₂, and LIN (SO₂C₂F₅)₂ are named.

The negative electrode current collector layer 24 is formed a metal foil, a metal mesh or the like. Metal used for forming the negative electrode current collector layer 24 is metal having favorable conductivity such as copper, nickel, titanium, or stainless steel. On a surface of the negative electrode current collector layer 24, for example, lithium metal or a lithium alloy is dissolved or is precipitated. In the above-mentioned description, “dissolved” is not limited to a case where lithium metal or a lithium alloy is completely dissolved, and includes a case where lithium metal or a lithium alloy is partially dissolved. That is, lithium metal or a lithium alloy may remain on the surface of the negative electrode current collector layer 24 in a discharging state of the energy storage device 2.

The energy storage device 2 may be bound by the binding member 3. The binding member 3 includes, for example, a case 31 that houses the energy storage device 2 and elastic members 32 that are disposed in the case 31 in a compressed state. The case 31 is, for example, a rectangular parallelepiped container, and includes: a case body 310 that is formed of a bottom surface portion 311 and a side surface portions 312; and a lid body 313 that closes an opening of the case body 310. The case body 310 (the bottom surface portion 311 and the side surface portions 312) and the lid body 313 are made of weldable metal such as stainless steel, aluminum, or an aluminum alloy, for example. Alternatively, the case body 310 (the bottom surface portion 311 and the side surface portion 312) and the lid body 313 may be formed of a resin. The energy storage devices 2 are housed in the case body 310 and, thereafter, the case body 310 is sealed by the lid body 313.

The elastic member 32 is disposed in a compressed state between the lowermost layer (the positive electrode current collector layer 21 in the example illustrated in FIG. 15) and the bottom surface portion 311 of the energy storage device 2, and between the uppermost layer (the negative electrode current collector layer 24 in the example illustrated in FIG. 15) and the lid body 313 of the energy storage device 2. The elastic member 32 is, for example, a rubber-like sheet. The elastic members 32 apply a binding force in the stacking direction (from above and below in the vertical direction in the drawing) to the energy storage device 2 by an elastic force that the elastic members 32 possess.

In the example illustrated in FIG. 15, the configuration is adopted where a binding force is applied to the energy storage device 2 by disposing the elastic members 32 inside the case 31. Alternatively, a binding force may be applied to the energy storage device 2 by filling the case 31 with a high pressure fluid. In this case, it is preferable that the fluid be a fluid that does not cause an undesired reaction with the battery material. For example, an inert gas such as nitrogen, dry air, or the like is used as such a fluid. Alternatively, the configuration may be adopted where the energy storage devices 2 may be sandwiched by plate members from both sides in the stacking direction, and the plate members may be connected to each other in a state where a binding force is applied to the energy storage devices 2 thus applying the binding force to the energy storage devices 2.

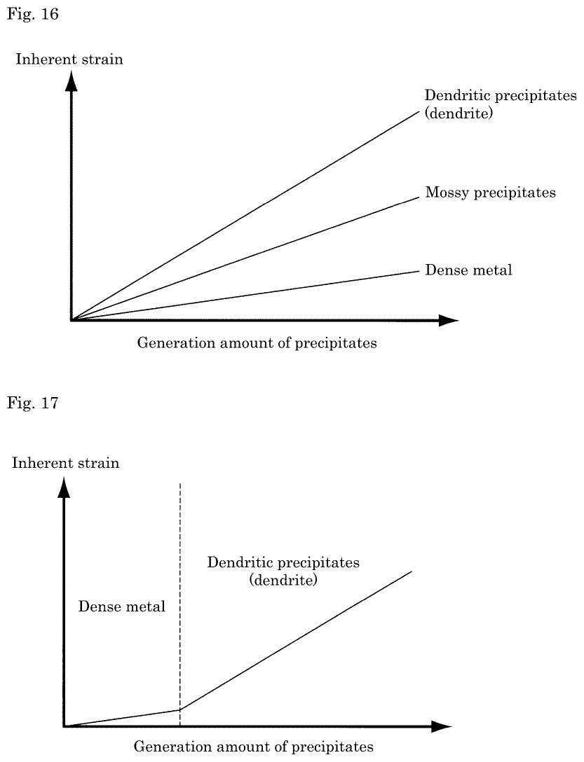

FIG. 16 is a graph illustrating an example of a relationship between a generation amount of precipitates and an inherent strain. In the graph illustrated in FIG. 16, a generation amount of precipitates is taken on an axis of abscissas, and an inherent strain is taken on an axis of ordinates. Due to the repetition of charging and discharging for a long time, precipitates may be precipitated inside the energy storage device 2. For example, in a case where lithium metal is used for forming the negative electrode of the energy storage device 2, there arises a possibility that lithium metal is sparsely precipitated on the surface of the negative electrode by repeated charging and discharging over a long period of time. There may be a case where the precipitation mode is dense.

As illustrated in the graph, an inherent strain of the energy storage device 2 is proportional to a precipitation amount of precipitates. However, A size of the inherent strain largely differs depending on a precipitation mode. Even with the same precipitation amount, the size of an inherent strain is relatively small in a case where dense metal is precipitated, and the size of an inherent strain is relatively large in a case where metal is precipitated sparsely. When mossy precipitates are precipitated, an inherent strain has an intermediate size between the above-mentioned both sizes.

FIG. 17 is a graph illustrating an example of a relationship between a generation amount of precipitates and an inherent strain. In the graph illustrated in FIG. 17, a generation amount of precipitates is taken on an axis of abscissas, and an inherent strain is taken on an axis of ordinates. The graph illustrates a mode where dense precipitates are precipitated at an initial stage of precipitation and, then, sparse precipitates are precipitated. The inherent strain of the energy storage device 2 is given as a value proportional to a generation amount of precipitates in both a stage where dense precipitates are precipitated and a stage where sparse lithium is precipitated.

The storage unit 12 of the estimation device 1 stores a function or a table for converting a generation amount of precipitates into an inherent strain of the energy storage device 2. The arithmetic operation unit 11 of the estimation device 1 looks up a function or a table stored in the storage unit 12, and calculates an inherent strain of the energy storage device 2 when a generation amount of the precipitates is given.

The arithmetic operation unit 11 estimates the distribution of a stress or a strain in the energy storage device 2 based on a calculated inherent strain.

For example, a relationship expression between a stress and a strain in a linear elastic body having no deformation anisotropy is expressed by Formula 30. Alternatively, expressions that express characteristics of an elastoplastic body, a brittle material or the like may be used depending on a constituent material of an object.

$$\\ \begin{matrix}( \begin{matrix}{σ}_{xx} \\ {σ}_{yy} \\ {σ}_{zz} \\ {σ}_{xy} \\ {σ}_{yz} \\ {σ}_{zx}\end{matrix} ) = ( \begin{matrix}λ + 2 μ & λ & λ & 0 & 0 & 0 \\ λ & λ + 2 μ & λ & 0 & 0 & 0 \\ λ & λ & λ + 2 μ & 0 & 0 & 0 \\ 0 & 0 & 0 & μ & 0 & 0 \\ 0 & 0 & 0 & 0 & μ & 0 \\ 0 & 0 & 0 & 0 & 0 & μ\end{matrix} ) ( ε + {ε}^{{}_{} 0} ) & [ Formula 30 ]\end{matrix}$$

$$\\ ε = ( \begin{matrix}{ε}_{xx} \\ {ε}_{yy} \\ {ε}_{zz} \\ {ε}_{xy} \\ {ε}_{yz} \\ {ε}_{zx}\end{matrix} ) {ε}^{{}_{} 0} = ( \begin{matrix}{ε}_{xx}^{{}_{} 0} \\ {ε}_{yy}^{{}_{} 0} \\ {ε}_{zz}^{{}_{} 0} \\ {ε}_{xy}^{{}_{} 0} \\ {ε}_{yz}^{{}_{} 0} \\ {ε}_{zx}^{{}_{} 0}\end{matrix} )$$

In Formula 30, a tensor that includes σᵢᵢ and σᵢⱼ as elements is expressed as a stress tensor. σᵢᵢ indicates a normal stress that acts on a surface where a normal line is directed in the i direction, and σᵢⱼ indicates a shear stress that acts on a surface where a normal line is directed in the j direction. The tensor described by Lamé constants λ, μ indicates an elastic tensor. The Lamé constants λ, μ are expressed by Young's modulus and Poisson's ratio. The Lamé constants λ, μ may be given as functions of a generation amount of precipitates. ϵ is a strain tensor and includes ϵᵢᵢ and ϵᵢⱼ as elements. ϵᵢᵢ indicates a normal stress that acts on a surface where a normal line is directed in the i direction, and σᵢⱼ indicates a shear stress in the j direction that acts on a surface where a normal line is directed in the i direction. ϵ⁰ is an inherent strain tensor and includes ϵᵢᵢ⁰ and ϵᵢⱼ⁰ as elements. ϵᵢᵢ⁰ indicates a normal inherent strain that acts on a surface where a normal line is directed in the i direction, and ϵᵢⱼ⁰ indicates a shear inherent strain in the j direction that acts on a surface where a normal line is directed in the i direction. In the embodiment 7, ϵᵢᵢ⁰, ϵᵢⱼ⁰ are given as a function of a generation amount of the precipitates.

The arithmetic operation unit 11 of the estimation device 1 gives an inherent strain to the member on which precipitates precipitate, and calculates the distribution of a stress or a strain by solving a stress-strain relationship equation expressed in Formula 30, and a balance equation between a force and a moment expressed in Formula 31 under an arbitrary binding condition.

$$\\ \begin{matrix}\{ \begin{matrix}\frac{\partial {σ}_{xx}}{\partial x} + \frac{\partial {σ}_{yx}}{\partial y} + \frac{\partial {σ}_{zx}}{\partial z} = 0 \\ \frac{\partial {σ}_{xy}}{\partial x} + \frac{\partial {σ}_{yy}}{\partial y} + \frac{\partial {σ}_{zy}}{\partial z} = 0 \\ \frac{\partial {σ}_{xz}}{\partial x} + \frac{\partial {σ}_{yz}}{\partial y} + \frac{\partial {σ}_{zz}}{\partial z} = 0\end{matrix} \{ \begin{matrix}{σ}_{xy} = {σ}_{yx} \\ {σ}_{yz} = {σ}_{zy} \\ {σ}_{xz} = {σ}_{zx}\end{matrix} & [ Formula 31 ]\end{matrix}$$

Hereinafter, the steps of processing performed by the estimation device 1 will be described.

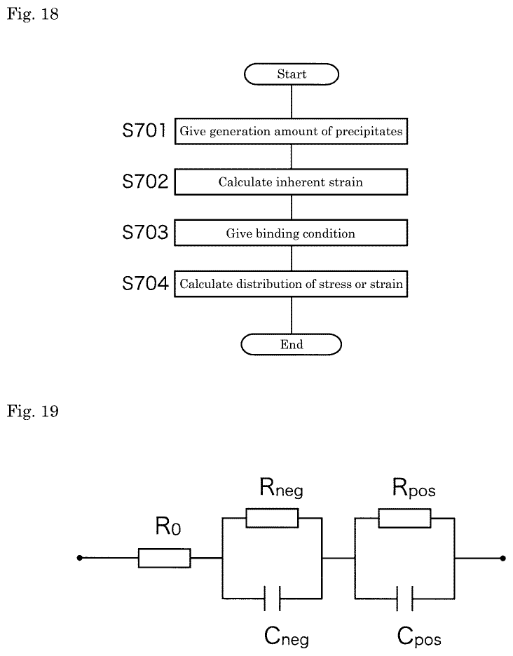

FIG. 18 is a flowchart illustrating the steps of calculating the stress-strain distribution. The arithmetic operation unit 11 gives a generation amount of precipitates to the energy storage device 2 that is a target to be simulated (step S701), and calculates an inherent strain of a member on which the precipitates are precipitated (step S702). In such a state, the arithmetic operation unit 11 may read a function or a table for converting a generation amount of the precipitates into an inherent strain from the storage unit 12, and may convert the generation amount into the inherent strain in accordance with the read function or the read table.

Next, the arithmetic operation unit 11 gives a binding condition to the energy storage device 2 (step S703), and calculates the distribution of a stress or a strain based on a stress-strain relationship expression and a force-moment balance expression based on Formula 30 and Formula 31 (step S704).

As has been described above, the estimation device 1 according to the embodiment 7 can calculate the distribution of a stress or a strain in the energy storage device 2 by taking into account a generation amount of precipitates that are precipitated inside the energy storage device 2.

### (Embodiment 8)

In an embodiment 8, the configuration is described where a generation rate of precipitates is calculated based on an internal stress in an energy storage device 2, and a generation amount of precipitates is calculated based on the calculated generation rate.

The generation of precipitates inside the energy storage device 2 is affected by a stress generated in a precipitate-generating reaction field (for example, a negative electrode surface). The generation rate of the precipitates is expressed as follows as a function of a stress generated in the precipitate-generating reaction field.

Rₚ=f(σ) (32)

In Formula 32, Rₚ indicates a generation rate of precipitates (kg/(s m²)), and o is a stress tensor (N/m²).

The generation of precipitates is affected not only by a stress but also by a change with a lapse of time in current density and overvoltage during charging and discharging. The generation rate of precipitates may be expressed in Formula 33.

Rₚ=f(i_{react}, η, σ, t) (33)

In Formula 33, i_{react} is a reaction current density (A/m²), and n is an overvoltage (V).

In a case where the generation rate of precipitates is given by Formula 32 (or Formula 33), the arithmetic operation unit 11 can calculate an amount of precipitates in accordance with an arithmetic operation expressed in Formula 34.

∫(∫∫Rₚ dS)dt (34)

The arithmetic operation unit 11 can calculate an inherent strain based on the calculated generation amount of the precipitates. The arithmetic operation unit 11 can estimate the distribution of a stress or a strain in the energy storage device 2 based on a calculated inherent strain.

The arithmetic operation unit 11 may calculate the distribution of the precipitates by Formula 35 using a generation amount of precipitates as area density, and may also calculate an inherent strain as the distribution.

∫Rₚdt (35)

Hereinafter, an example of an expression that expresses a generation rate Rₚ is described.

In a case where a generation reaction of precipitates is regarded as an electrode reaction, the reaction current density is expressed as follows using a Butler Bormer equation.

$$\\ \begin{matrix}{i}_{react \_ p} = {i}_{0 \_ p} [ exp ( \frac{{α}_{a} nF η}{RT} ) - exp ( - \frac{{α}_{c} nF η}{RT} ) ] & [ Formula 36 ]\end{matrix}$$

$$\\ η = {ϕ}_{s} - {ϕ}_{l} - {E}_{eq}$$

$$\\ {i}_{0 \_ p} = f ( {i}_{react} , η , σ , t )$$

In formula, i_{react_p} indicates a reaction current density (A/m²) in the generation reaction of precipitates, and i_{0_p} is an exchange current density (A/m²). αₐ and α_{c} respectively indicate a charge transfer coefficient of an oxidation reaction and a charge transfer coefficient of a reduction reaction, n indicates the number of electrons contributing to the reaction, F indicates a Faraday constant (C/mol), η expresses an overvoltage (V), R indicates a gas constant (J/(mol K)), and T indicates a temperature (K). φₛ indicates a solid phase potential (V), φ₁ indicates a liquid phase potential (V), and E_{eq} indicates an equilibrium potential (V).

When the reaction current density i_{react_p} is given by Formula 36, the generation rate Rₚ of precipitates expressed as Formula 37.

$$\\ \begin{matrix}{R}_{p} = \frac{{M}_{Li} {i}_{react \_ p}}{F} & [ Formula 37 ]\end{matrix}$$

In Formula 37, M_{Li} indicates a molar mass (kg/mol) of precipitates (for example, lithium metal). In such a state, a swelling amount Δ1 (m) of the electrode is calculated by Formula 38. ρₚ indicates density of precipitates (kg/m³).

$$\\ \begin{matrix}Δ l = {\int }_{0}^{t} ( \frac{{R}_{p}}{{ρ}_{p}} ) dt & [ Formula 38 ]\end{matrix}$$

Assuming that a size of an electrode with respect to a direction perpendicular to a precipitation surface as I (m) when a precipitation amount of precipitates is zero, and precipitates of Δ1 are generated on the electrode, ϵ₁ is defined by the following Formula 39. Formula 39 expresses are compressive strain in a precipitation direction that is generated in a case where it is assumed that an electrode portion on which precipitates are generated is not deformed at all even when the precipitates are precipitated.

$$\\ \begin{matrix}{ε}_{l} = \frac{- Δ l}{l + Δ l} & [ Formula 39 ]\end{matrix}$$

Assuming that a unit vector in the mixture swelling direction (the direction perpendicular to a precipitation surface) due to the generation of precipitates as n=(nₓ, n_{y}, n_{z}), an inherent strain tensor ϵ⁰ is expressed as Formula 40.

$$\\ \begin{matrix}{ε}^{{}_{} 0} = ( \begin{matrix}{ε}_{l} {n}_{x} \\ {ε}_{l} {n}_{y} \\ {ε}_{l} {n}_{z} \\ 0 \\ 0 \\ 0\end{matrix} ) & [ Formula 40 ]\end{matrix}$$

The arithmetic operation unit 11 of the estimation device 1 derives the inherent strain tensor ϵ⁰ based on, for example, Formula 36 to Formula 40, and calculates the distribution of a stress or a strain in the energy storage device 2 by using Formula 30 and Formula 31 described in the embodiment 7.

As described above, the estimation device 1 according to the embodiment 8 can perform calculation by linking a generation amount of the precipitates with the stress/strain distribution.

### (Embodiment 9)

In an embodiment 9, the configuration is described where an electrochemical phenomenon of an energy storage device 2 is simulated by taking into account a generation amount of precipitates and a stress field.

An amount of generation of precipitates and a stress generated inside the energy storage device 2 affect battery characteristics of the energy storage device 2. The inherent conductivity, the liquid phase conductivity, and the exchange current density of the energy storage device 2 are expressed as follows as functions of the generation amount of precipitates, a stress, and time.

i₀=f(mₚ, σ, t)

σₗ=g(mₚ, σ, t)

σₛ=h(mₚ, σ, t) (41)

In Formula 41, i₀ indicates an exchange current density (A/m²), σ₁ indicates a liquid phase conductivity (S/m), σₛ indicates a solid phase conductivity (S/m), mₚ indicates a generation amount (kg) of precipitates or a surface density (kg/m²) of precipitates, σ indicates a stress tensor, and t indicates time.

The arithmetic operation unit 11 can simulate an electrochemical phenomenon of the energy storage device 2 that takes into account the influence of generation amount of the precipitates and a stress by solving an electrochemical model such as the Newman model using Formula 41.

The Newman model is described by the Nernst-Planck equation, the charge conservation equation, the diffusion equation, the Butler-Volmer equation, and the Nernst equation described below.

The Nernst-Planck equation is an equation for solving ion diffusion in an electrolyte or in an electrode, and is expressed by the following formula.

$$\\ \begin{matrix}∇ \cdot [ - {σ}_{l} ∇ {ϕ}_{l} + \frac{2 {σ}_{l} RT}{F} ( 1 + \frac{\partial ln f}{\partial ln {c}_{l}} ) ( 1 - {t}_{+} ) ∇ ln {c}_{l} ] = {i}_{tot}^{{}_{} l} & [ Formula 42 ]\end{matrix}$$

In Formula 42, σ₁ indicates phase conductivity (S/m), φ₁ indicates a liquid phase potential (V), R indicates a gas constant (J/(K·mol)), T indicates a temperature (K), F indicates Faraday constant (C/mol), f indicates an activity coefficient, c₁ indicates an ion concentration of the electrolyte (mol/m³), and t₊ is a cation transport number. The i¹ₜₒₜ in Formula 42 indicates the gushing (A/m³) of a liquid phase current.

A charge storage formula is a formula expressing electron conduction in an active material and a current collecting foil, and is expressed by the following formula.

∇·(σₛ∇ϕₛ)=−iₜₒₜ^{s} (43)

In Formula 43, is indicates a solid phase current density(A/m²), φₛ indicates a solid phase potential (v), and σₛ indicates a solid phase conductivity (S/m). The i^{s}ₜₒₜ in Formula 43 indicates the gushing (A/m³) of the solid-phase current.

The diffusion equation is an equation expressing the diffusion of an active material in active particles, and is expressed by the following formula.

$$\\ \begin{matrix}\frac{\partial {c}_{s}}{\partial t} = ∇ \cdot ( {D}_{s} ∇ {c}_{s} ) & [ Formula 44 ]\end{matrix}$$

In Formula 44, cₛ indicates the active material concentration in a solid phase (mol/m³), tis time (s), and Dₛ indicates the diffusion coefficient in a solid phase (m²/s).

The Butler-Volmer equation is an equation expressing the relationship between a reaction current generated by a charge transfer reaction generated at an interface between a solid phase and a liquid phase and an activation overvoltage. The Nernst equation is an equation expressing an equilibrium potential that is a factor for determining an activation overvoltage.

$$\\ \begin{matrix}{i}_{react} = {i}_{0} [ exp ( \frac{{α}_{a} nF η}{RT} ) - exp ( - \frac{{α}_{c} nF η}{RT} ) ] & [ Formula 45 ]\end{matrix}$$

$$\\ η = {ϕ}_{s} - {ϕ}_{l} - {E}_{eq}$$

$$\\ {E}_{eq} = {E}^{{}_{} 0} + \frac{RT}{nF} ln ( \frac{{a}_{Ox}}{{a}_{Red}} )$$

In Formula 45, i_{react} indicates a reaction current density (A/m²), i₀ indicates an exchange current density (A/m²), αₐ and α_{c} indicate respectively transition coefficients of an oxidation reaction and a reduction reaction, η indicates an activation overvoltage (V), φₛ indicates a solid phase potential (V), φ₁ indicates a liquid phase potential (V), E_{eq} indicates an equilibrium potential (V), E₀ is a standard electrode potential (V), n indicates the number of electrons contributing to an oxidation-reduction reaction, and a_{Ox} and a_{Red} indicate active amounts of chemical species before and after the reaction. As the Butler-Volmer formula, a formula obtained by modifying the Butler-Volmer formula based on experimental values is used alternatively. For example, the Butler-Volmer formula can be modified as desired such that an exchange current density is converted into a function of active material concentration or ion concentration, or actually measured data of an SOC or an open circuit potential are used as an open circuit potential in place of calculating an equilibrium potential E_{eq} using the Nernst formula. The respective parameters used in Formula 42 to Formula 45 described above may be described as functions of other physical quantities.

In the embodiment 9, the Newman model is described as an example of the physical model of the energy storage device 2. In describing the charging and discharging characteristics, alternatively, a model other than a physical model such as an equivalent circuit model or a polynomial model may be used.

FIG. 19 is a circuit diagram illustrating an example of an equivalent circuit model. The equivalent circuit model of the energy storage device 2 is expressed by a combination of a resistor and a capacitance component. In the equivalent circuit model illustrated in FIG. 19, R₀ indicates an ohmic resistance component, Rₚₒₛ indicates a reaction resistance component of a positive electrode, Cₚₒₛ indicates a capacitance component of the positive electrode, R_{neg} indicates a reaction resistance component of a negative electrode, and C_{neg} indicates a capacitance component of the negative electrode. However, the equivalent circuit model illustrated in FIG. 19 is provided for an exemplifying purpose. There is no limitation on the type of the combination of electric circuit elements, that is the combination of the electric circuit elements in series or in parallel, the number and the type of electric circuit elements.

In a case where an electrochemical phenomenon of the energy storage device 2 is evaluated by 1D using an equivalent circuit model, the estimation device 1 may estimate each resistance and each electric capacity based on the following Formula 46.

Rₚₒₛ=f_{R}(mₚ, σ, t) Cₚₒₛ=f_{C}(mₚ, σ,t)

R_{neg}=g_{R}(mₚ, σ, t) C_{neg}=g_{C}(mₚ, σ, t)

R₀=h_{R}(mₚ, σ, t) (46)

In Formula 46, mₚ indicates a generation amount (kg) of precipitates or an area density (kg/m²) of the precipitates, σ indicates a stress, and t indicates time.

As has been described above, the estimation device 1 according to in the embodiment 9, can simulate an electrochemical phenomenon of the energy storage device 2 based on a generation amount of precipitates and a stress field.

### (Embodiment 10)

In the embodiment 10, the description is made with respect to the configuration where a thermal phenomenon of an energy storage device 2 is simulated based on a generation amount of precipitates and a precipitation mode.

A generation amount of precipitates and a precipitation mode inside the energy storage device 2 affect a thermal phenomenon of the energy storage device 2. A heat generation reaction rate, thermal conductivity, a specific heat, and density of the energy storage device 2 are expressed as follows as functions of a generation amount of precipitates and a precipitation mode.

Q_{TR}=f(mₚ, α) Cₚ=h(mₚ, α)

k=g(mₚ, α) ρ=q(mₚ, α) (47)

In Formula 47, Q_{TR} indicates generated heat (W/m³), Cₚ indicates specific heat (J/(kg K)), k indicates thermal conductivity (W/(m K)), and ρ indicates density (kg/m³). mₚ indicates a generation amount (kg) of precipitates, and α indicates a coefficient set in accordance with a precipitation mode. The coefficient α is given as a value that is proportional to a specific surface area of the precipitates, for example. Alternatively, the coefficient α may be given as a value proportional to (absolute value of inherent strain/a generation amount of precipitates).

The arithmetic operation unit 11 can simulate are thermal phenomenon of the energy storage device 2 while taking into account a generation amount of precipitates and a precipitation mode by solving a thermal conduction equation using Formula 47. The mal conduction equation is expressed by Formula 48.

$$\\ \begin{matrix}ρ {C}_{p} \frac{\partial T}{\partial t} = ∇ ( k ∇ T ) + Q & [ Formula 48 ]\end{matrix}$$

In Formula 48, Q indicates generated heat (W/m³), and corresponds to Q_{TR} in Formula 47.

The arithmetic operation unit 11 may calculate Joule heat generation based on the following formula by combining Formula 48 with the electrochemical model described in the embodiment 9.

Q₁32 iₗ∇ϕₗ Q₂=iₛ·ϕₛ Q₃=i_{react}η (49)

In Formula 49, i₁ indicates liquid phase current density (A/m²), φ₁ indicates liquid phase conductivity (A/m²), is indicates solid phase current density (A/m²), and φₛ indicates solid phase conductivity (A/m²).

As described above, the estimation device 1 according to the embodiment 10 can simulate the thermal phenomenon of the energy storage device 2 based on a generation amount of precipitates and a precipitation mode of the precipitates.

### (Embodiment 11)

In the embodiment 11, the description is made with respect to the configuration where the distribution of a stress or a strain of an energy storage device 2 is calculated by taking into account an amount of a gas generated inside the energy storage device 2.

There may be a case where a gas is generated inside the energy storage device 2 by the repetition of charging and discharging. In the case where a gas is generated inside the energy storage device 2, the energy storage device 2 expands and a strain is generated in the energy storage device 2 by the expansion. In the embodiment 11, the description is made with respect to a method of calculating the distribution of a stress or a strain in the energy storage device 2 by taking into account a generation amount of a gas.

A generation amount of a gas in the energy storage device 2 is given by various equations. For example, in a case where irregularities exist in reaction so that the generation of a gas is likely to be increased when a current is concentrated, a gas generation amount n_{gas} (mol) is calculated based on the reaction current density i_{react} described above.

$$\\ \begin{matrix}{n}_{gas} = \int {}_{} {}_{} [ \frac{1}{F} \int {}_{} \{ J ( {i}_{react} - {ave\_i}_{react} ) \} dS ] dt & [ Formula 50 ]\end{matrix}$$

$$\\ J = \{ \begin{matrix}1 … 0 < ( {i}_{react} - {ave\_i}_{react} ) \\ 0 … ( {i}_{react} - {ave\_i}_{react} ) < 0\end{matrix}$$

In Formula 50, J is a variable that becomes 1 in a case where the local reaction current density is higher than an average reaction current density (in a case where a current is concentrated), and becomes 0 in a case where the local reaction current density is not higher than the average reaction current density. ave_i_{react} is an average reaction current density (A/m²).

In such a state, an internal pressure p (N/m²) in the energy storage device 2 due to the generation of a gas is calculated by the following Formula 51.

$$\\ \begin{matrix}p = \frac{( {n}_{gas} + {n}_{0} ) RT}{v} & [ Formula 51 ]\end{matrix}$$

In the formula, no is an initial gas amount (mol), and v is a volume (m³) of a gap inside the energy storage device. Strictly speaking, the calculation of the internal pressure in the energy storage device 2 is performed in accordance with the relation of Gibbs=Duem (Gibbs=Duem equation). However, Formula 51 may be used for simplifying the calculation. Formula 51 may be used on the assumption that the gas is an ideal gas. However, a state equation of a gas may be used by taking into account an intermolecular force.

In this case, a stress tensor σ is expressed by the following formula using the internal pressure p in the energy storage device 2.

$$\\ \begin{matrix}σ = ( \begin{matrix}{σ}_{xx} & {σ}_{yx} & {σ}_{zx} \\ {σ}_{xy} & {σ}_{yy} & {σ}_{zy} \\ {σ}_{xz} & {σ}_{yz} & {σ}_{zz}\end{matrix} ) = ( \begin{matrix}p & 0 & 0 \\ 0 & p & 0 \\ 0 & 0 & p\end{matrix} ) & [ Formula 52 ]\end{matrix}$$

The arithmetic operation unit 11 of the estimation device 1 calculates the distribution of a stress or a strain by taking into account the stress expressed by Formula 52 and by solving a stress-strain relationship equation expressed by Formula 30 and a balance formula between a force and a moment expressed in Formula 31.

As has been described above, the estimation device 1 according to the embodiment 11 can calculate the distribution of a stress or a strain in the energy storage device 2 by taking into account an amount of gas generated inside the energy storage device 2.

In the present invention, it should be construed that the embodiments disclosed herein are illustrative in all respects and are not limitative. The scope of the present invention is not defined by the description described above but is defined by the claims, and includes meanings equivalent to the claims and all modifications that fall within the scope of claims.

For example, the energy storage device 2 may be a module in which a plurality of cells are connected in series, a bank in which a plurality of modules are connected in series, a domain in which a plurality of banks are connected in parallel, or the like.

1. An estimation device comprising:
an acquisition unit configured to acquire data on a strain generated in an energy storage device; and
an estimation unit configured to estimate an internal stress in the energy storage device based on the data acquired by the acquisition unit using a simulation model that expresses a dynamic state inside the energy storage device.

2. The estimation device according to claim 1, wherein
the simulation model includes, as parameters, an inherent strain in the energy storage device, and a binding force applied to the energy storage device, and
the estimation device is configured to output data relating to the internal stress in the energy storage device in response to inputting of data on the strain.

3. The estimation device according to claim 2, wherein the inherent strain is a strain in the energy storage device generated attributed to at least one of isolation of active material particles, a growth of precipitates, and thermal expansion of the energy storage device.

4. The estimation device according to claim 1, wherein the estimation unit includes a state estimation unit provided with a nonlinear filter.

5. The estimation device according to claim 1, wherein the estimation unit estimates an internal resistance of the energy storage device as a function of the internal stress.

6. The estimation device according to claim 1, wherein the energy storage device is an all-solid-state battery in which an electrolyte is a solid material.

7. The estimation device according to claim 1, wherein the energy storage device is a battery having a negative electrode made of metal lithium.

8. An estimation device comprising an arithmetic operation unit configured to simulate, using a simulation model that includes a contact area between active material particles and a solid electrolyte as parameter, an electrochemical phenomenon of an all-solid-state battery that includes the solid electrolyte.

9. An estimation device comprising an arithmetic operation unit that, with respect to an energy storage device in which precipitates are generated corresponding to charging and discharging, calculates an inherent strain of the energy storage device based on a generation amount and a precipitation mode of the precipitates, and calculates the distribution of a stress or a strain generated in the energy storage device based on the calculated inherent strain.

10. An estimation method causing a computer to perform processing to acquire data relating to a strain generated in an energy storage device, and to estimate an internal stress of the energy storage device based on acquired data using a simulation model that expresses a dynamic state inside the energy storage device.

11. The estimation method of causing a computer to perform processing to simulate, using a simulation model that includes a contact area between active material particles and a solid electrolyte as a parameter, an electrochemical phenomenon of an all-solid-state battery that includes the solid electrolyte.

12. An estimation method used with respect to an energy storage device in which precipitates are generated corresponding to charging and discharging, the estimation method causing a computer to perform processing to calculate an inherent strain of the energy storage device based on a generation amount and a precipitation mode of precipitates, and to calculate distribution of a stress or a strain generated in the energy storage device based on the calculated inherent strain.

13. A computer program causing a computer to perform processing to simulate, using a simulation model that includes a contact area between active material particles and a solid electrolyte as a parameter, an electrochemical phenomenon of an all-solid-state battery that includes the solid electrolyte.

14. The computer program according to claim 13, wherein the simulation model defines a relationship between the contact area and an effective diffusion coefficient of the active material particles, and the computer program causes the computer to perform processing to estimate the effective diffusion coefficient of the active material particles based on a value of the contact area.

15. The computer program according to claim 13, wherein the simulation model defines a relationship between the contact area and an effective ionic conductivity of the active material particles, and the computer program causes the computer to perform processing to estimate the effective ionic conductivity of the active material particles based on a value of the contact area.

16. The computer program according to claim 13, wherein
the contact area is a function of an internal stress of the all-solid-state battery, and
the computer program causes the computer to perform processing to simulate an electrochemical phenomenon of the all-solid-state battery based on a value of the internal stress.

17. The computer program according to claim 16, wherein
the computer program causes the computer to perform processing to acquire measured data relating to a strain generated in the all-solid-state battery from a strain sensor that measures the strain, and
to estimate an internal stress of the all-solid-state battery based on the acquired measured data using a model that expresses a dynamic state inside the all-solid-state battery.

18. The computer program according to claim 16, wherein
an internal resistance of the all-solid-state battery is a function of the internal stress, and
the computer program causes the computer to perform processing to estimate a value of the internal resistance based on a value of the internal stress.

19. A computer program used with respect to an energy storage device in which precipitates are generated corresponding to charging and discharging, the computer program causing a computer to perform processing to calculate an inherent strain of the energy storage device based on a generation amount and a precipitation mode of precipitates, and to calculate distribution of a stress or a strain generated in the energy storage device based on the calculated inherent strain.

20. The computer program according to claim 19, wherein
a generation rate of the precipitates is described in the computer program as a function of a stress generated in a generation reaction field, and
the computer program causes the computer to perform processing to calculate the generation amount of the precipitates based on the generation rate of the precipitates calculated by the function.

21. The computer program according to claim 19, wherein the computer program causes the computer to perform processing to simulate an electrochemical phenomenon of the energy storage device based on the generation amount and a stress field.

22. The computer program according to claim 19, wherein the computer program causes the computer to perform processing to simulate a thermal phenomenon of the energy storage device based on the generation amount and a precipitation mode.

23. The computer program according to claim 19, wherein
the computer program causes the computer to perform processing to calculate a gas generation amount inside the energy storage device, and
to calculate distribution of a stress or a strain generated in the energy storage device based on the calculated gas generation amount.
